(19) United States
(12) Patent Application Publication
(10) Pub. No.: US 2014/0061616 A1
(43) Pub. Date: Mar. 6, 2014

(54) ORGANIC SEMICONDUCTOR MATERIAL, COATING LIQUID CONTAINING THE MATERIAL, AND ORGANIC THIN FILM TRANSISTOR

(71) Applicants: Misa Sunagawa, Sodegaura-shi (JP); Masatoshi Saito, Sodegaura-shi (JP); Hidetsugu Ikeda, Sodegaura-shi (JP); Yoichi Ikeda, Sodegaura-shi (JP); Hirofumi Kondo, Sodegaura-shi (JP); Kota Terai, Sodegaura-shi (JP)

(72) Inventors: Misa Sunagawa, Sodegaura-shi (JP); Masatoshi Saito, Sodegaura-shi (JP); Hidetsugu Ikeda, Sodegaura-shi (JP); Yoichi Ikeda, Sodegaura-shi (JP); Hirofumi Kondo, Sodegaura-shi (JP); Kota Terai, Sodegaura-shi (JP)

(73) Assignee: IDEMITSU KOSAN CO., LTD., Tokyo (JP)

(21) Appl. No.: 13/997,929

(22) PCT Filed: Dec. 23, 2011
(86) PCT No.: PCT/JP2011/007241

§ 371 Date: Sep. 30, 2013

(30) Foreign Application Priority Data
Dec. 28, 2010 (JP) 2010-292907

(51) Int. Cl. H01L 51/00

(52) U.S. Cl. CPC H01L 51/0074
USPC 257/40; 549/41; 252/500

(57) ABSTRACT

An organic semiconductor material is represented by the following formula (1), wherein two or more of R₁ to R₆ are an alkyl group.

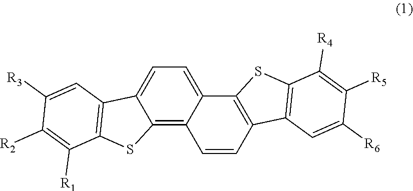

### TECHNICAL FIELD

The invention relates to an organic semiconductor material, a coating liquid that includes the organic semiconductor material, and an organic thin film transistor produced using the coating liquid. The invention also relates to a device that includes the organic thin film transistor.

### BACKGROUND ART

A thin film transistor (TFT) is widely used as a switching device for a display (e.g., liquid crystal display). A typical TFT has a configuration in which a gate electrode, an insulator layer, and a semiconductor layer are sequentially stacked on a substrate, and a source electrode and a drain electrode are formed on the semiconductor layer at a given interval from each other. The organic semiconductor layer forms a channel region, and an ON/OFF operation is implemented by controlling a current that flows between the source electrode and the drain electrode by applying a voltage to the gate electrode.

A TFT has been produced using amorphous or polycrystalline silicon. However, a CVD system that is used to produce a TFT using amorphous or polycrystalline silicon is very expensive, and a considerable cost is required when producing a large display that utilizes a TFT, Moreover, since a process that forms an amorphous or polycrystalline silicon film is performed at a significantly high temperature, the type of material that can be used as the substrate is limited (i.e., a light resin substrate or the like cannot be used).

In order to solve the above problems, a TFT that utilizes an organic material instead of amorphous or polycrystalline silicon (hereinafter may be referred to as “organic TFT”) has been proposed. A vacuum deposition method, a coating method, and the like have been known as a film-forming method used when producing a TFT using an organic material. These methods make it possible to produce a large device (i.e., increase the degree of integration and the size of a TFT integrated circuit) while suppressing an increase in production cost. Moreover, since a relatively low process temperature can be employed when forming a film, various substrate materials can be selected. Therefore, practical application of the organic TFT has been hoped for, and extensive studies have been conducted. In particular, since an improvement in material utilization efficiency and a significant reduction in cost are expected to be achieved by utilizing the coating method, an organic semiconductor material that is suitable for the coating method has been desired.

A practical organic TFT is required to exhibit high carrier mobility and excellent storage stability.

When forming a film using the coating method, the organic semiconductor material must be soluble in a solvent, differing from the case of forming a film using the vacuum deposition method. An organic semiconductor material that exhibits high carrier mobility (hereinafter may be referred to as “mobility”) is normally an organic compound that has an extended π-conjugated system, and is dissolved in a solvent to only a small extent.

Since the solubility of a material in a solvent is basically improved by heating the material, a coating liquid of the organic semiconductor material may be produced by heating the organic semiconductor material. In this case, however, the number of parameters (e.g., the amount of the solvent evaporated during production of the coating liquid, and temperature control during the film-forming process) that must be controlled increases, and power consumption may also increase. Therefore, an organic semiconductor material that exhibits high carrier mobility, excellent storage stability, and high solubility has been desired.

A polymer (e.g., conjugated polymer and polythiophene), a fused ring compound (e.g., metallophthalocyanine compound and pentacene), and the like have been proposed as a p-type organic semiconductor material used for the organic TFT.

In particular, pentacene (i.e., acene-type fused ring compound) has attracted attention as a material that exhibits high carrier mobility almost equal to that of amorphous silicon due to its extended 7-conjugated system, and has been extensively studied. However, pentacene is not suitable for the coating method due to low solubility in a solvent, and exhibits low storage stability in air.

A polythiophene (e.g., poly(3-hexylthiophene)) is an organic semiconductor material that is suitable for the coating method from the viewpoint of solubility in a solvent. However, a polythiophene exhibits low storage stability in air.

In view of the above situation, research and development of a coating-type organic semiconductor that exhibits storage stability in air and exhibits high carrier mobility are being conducted.

Non-patent Document 1 discloses 2,7-dioctylnaphtho[1,2-b:5,6-b′]dithiophene (i.e., a four-ring fused ring compound in which two thiophene skeletons are fused with a naphthalene ring) as an organic semiconductor material that exhibits solubility and oxidation stability. Non-patent Document 1 states that 2,7-dioctylnaphtho[1,2-b:5,6-b′]dithiophene exhibits solubility, but produces a coating film that exhibits poor properties (e.g., low carrier mobility).

Patent Document 1 discloses an organic transistor in which a six-ring fused ring compound (in which two benzothiophene skeletons are fused with a naphthalene ring) is used for an organic semiconductor layer, and states that the compound exhibits high charge mobility, a large current ON/OFF ratio, and excellent storage stability. Patent Document 1 also discloses an organic transistor of which the organic semiconductor layer is formed by a wet process using the compound. However, the organic semiconductor material disclosed in Patent Document 1 does not exhibit sufficient solubility, and does not improve the mobility in the organic TFT.

Since various coating-type organic semiconductor materials that have been proposed to date do not have properties that ensure practical performance, a material that exhibits high carrier mobility, exhibits storage stability in air, and exhibits high solubility in a solvent has been desired.

### RELATED-ART DOCUMENT

### Patent Document

Patent Document 1: JP-A-2009-267134

### Non-Patent Document

Non-patent Document 1: J. Org. Chem. Vol. 75, No. 4, 2010, pp. 1228-1234

### SUMMARY OF THE INVENTION

An object of the invention is to provide an organic semiconductor material that exhibits high carrier mobility, exhibits storage stability in air, and exhibits high solubility in a solvent.

Another object of the invention is to provide a coating liquid that includes the organic semiconductor material, and an organic thin film transistor produced using the coating liquid.

Several aspects of the invention provide the following organic semiconductor material and the like.

1. An organic semiconductor material represented by a formula (1),

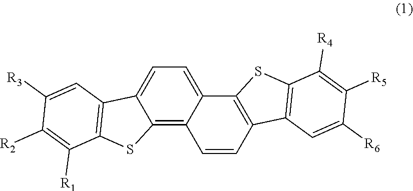

wherein R₁, R₃, R₄, and R₆ are independently a hydrogen atom, a linear alkyl group having 3 to 20 carbon atoms, or a branched alkyl group having 3 to 40 carbon atoms, and
R₂ and R₅ are independently a hydrogen atom, a linear alkyl group having 3 to 11 carbon atoms, or a branched alkyl group having 3 to 40 carbon atoms,
provided that two or more of R₁ to R₆ are an alkyl group.
2. The organic semiconductor material according to 1, wherein R₁, R₃, R₄, and R₆ are a hydrogen atom.
3. The organic semiconductor material according to 1, wherein R₁, R₂, R₄, and R₅ are a hydrogen atom.
4. The organic semiconductor material according to 1, wherein R₂, R₃, R₅, and R₆ are a hydrogen atom.
5. The organic semiconductor material according to 1, the organic semiconductor material being represented by

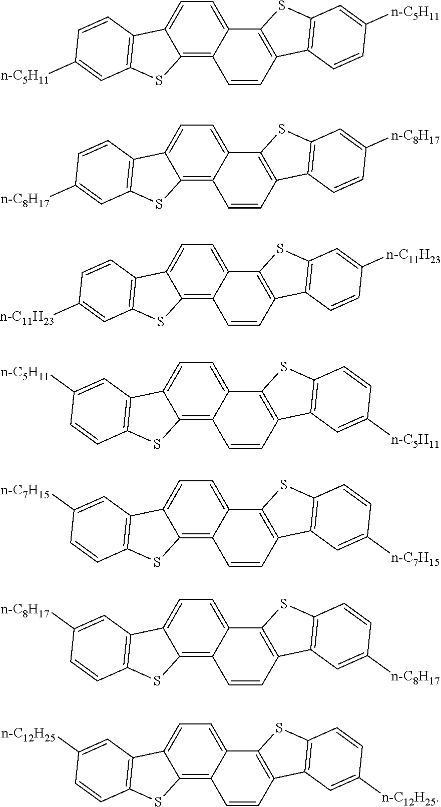

6. An organic semiconductor material represented by a formula (5),

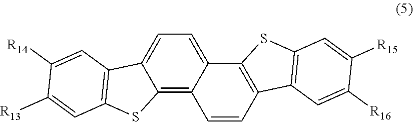

wherein R₁₃, R₁₄, R₁₅, and R₁₆ are independently a linear alkyl group having 3 to 11 carbon atoms or a branched alkyl group having 3 to 40 carbon atoms.
7. A coating liquid including the organic semiconductor material according to any one of 1 to 6, and an organic solvent.
8. An organic thin film transistor produced using the coating liquid according to 7.
9. An organic thin film transistor including an organic semiconductor layer produced using the coating liquid according to 7.
10. The organic thin film transistor according to 8 or 9, including a source electrode and a drain electrode, and emitting light by utilizing a current that flows between the source electrode and the drain electrode, wherein emission of light is controlled by applying a voltage to a gate electrode
11. The organic thin film transistor according to 10, wherein one of the source electrode and the drain electrode comprises a material that has a work function of 4.2 eV or more, and the other of the source electrode and the drain electrode comprises a material that has a work function of 4.3 eV or less.
12. The organic thin film transistor according to 10 or 11, including a buffer layer between the source electrode and drain electrode, and the organic semiconductor layer.
13. A device including the organic thin film transistor according to any one of 8 to 12.

The invention thus provides an organic semiconductor material that exhibits high carrier mobility, exhibits storage stability in air, and exhibits high solubility in a solvent.

### BRIEF DESCRIPTION OF DRAWINGS

FIG. 1 is a view illustrating an example of the device configuration of an organic thin film transistor according to the invention.

FIG. 2 is a view illustrating an example of the device configuration of an organic thin film transistor according to the invention.

FIG. 3 is a view illustrating an example of the device configuration of an organic thin film transistor according to the invention.

FIG. 4 is a view illustrating an example of the device configuration of an organic thin film transistor according to the invention.

FIG. 5 is a view illustrating an example of the device configuration of an organic thin film transistor according to the invention.

FIG. 6 is a view illustrating an example of the device configuration of an organic thin film transistor according to the invention.

### DESCRIPTION OF EMBODIMENTS

An organic semiconductor material according to the invention is a compound represented by the following formula (1).

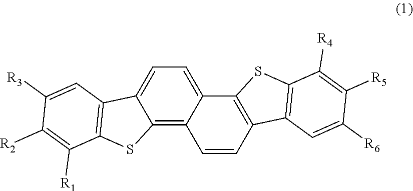

wherein R₁, R₃, R₄, and R₆ are independently a hydrogen atom, a linear alkyl group having 3 to 20 carbon atoms, or a branched alkyl group having 3 to 40 carbon atoms, and
R₂ and R₅ are independently a hydrogen atom, a linear alkyl group having 3 to 11 carbon atoms, or a branched alkyl group having 3 to 40 carbon atoms,
provided that two or more of R₁ to R₆ are an alkyl group.

The term “organic semiconductor” used herein refers to a material that functions as a semiconductor layer of an organic TFT, and exhibits TFT characteristics. The material exhibits a field-effect mobility calculated by the expression (A) (described later) of 1×10⁻³ cm²/Vs or more or 1×10⁻² cm²/Vs or more as the TFT characteristics.

The organic semiconductor material according to the invention has a six-ring fused ring structure as a basic structure wherein two thiophene rings are fused with a naphthalene ring, and a benzene ring is fused with each thiophene ring. A plurality of constitutional isomers of such a fused ring structure exist. Among these, a naphtho[1,2-b:5,6-b]benzo[b]dithiophene skeleton included in the comparative compound (2) (described later) is preferable from the viewpoint of mobility and the effect of an alkyl substituent. Note that the naphtho[1,2-b:5,6-b′]benzo[b]dithiophene skeleton is insoluble in an organic solvent. Moreover, favorable effects on mobility due to the alkyl substituents represented by R₁ to R₆ cannot be expected.

In the organic semiconductor material according to the invention, it is considered that the alkyl substituents represented by R₁ to R₆ contribute to intermolecular interaction due to the Van der Weals force, and exert favorable effects on mobility by preventing a decrease in crystallinity, and the degree of freedom of the conformational shift of R₁ to R₆ influences solubility.

Therefore, the organic semiconductor material according to the invention makes it possible to suppress a decrease in crystallinity that influences mobility, and achieve high solubility in a solvent particularly when two or more of R₁ to R₆ are a linear alkyl group or a branched alkyl group having a specific number of carbon atoms.

It is expected that an increase in heat resistance is achieved when the number of carbon atoms of the alkyl groups represented by R₁ to R₆ in the formula (1) is 12 or less. It is expected that crystal packing becomes dense, and an increase in mobility is achieved due to intermolecular interaction between the alkyl chains when the alkyl chains represented by R₁ to R₆ are long.

As for R₁ to R₆ in the formula (1), it is preferable that R₁, R₃, R₄, and R₆ may be hydrogen atoms; R₁, R₂, R₄, and R₅ may be hydrogen atoms; or R₂, R₃, R₅, and R₆ in the formula (1) may be hydrogen atoms.

Specifically, the compound represented by the formula (1) is preferably a compound among compounds represented by the following formulas.

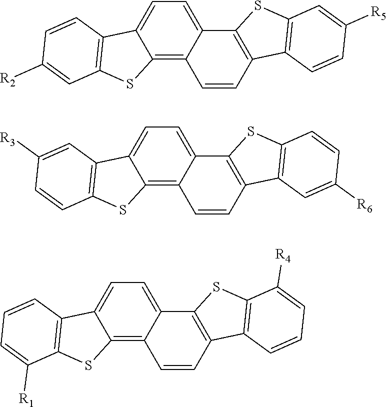

The compound represented by the formula (1) is more preferably the following compound among the compounds represented by the above formulas since high mobility and high solubility are obtained. It is considered that high mobility is obtained due to suppression of a decrease in crystallinity.

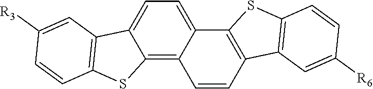

As for R₁ to R₆ in the formula (1), it is more preferable that R₁, R₃, R₄, and R₆ may be hydrogen atoms, and R₂ and R₅ in the formula (1) may be independently linear alkyl groups having 3 to 11 carbon atoms or a branched alkyl group having 3 to 40 carbon atoms. It is still more preferable that R₂ and R₅ may be independently a linear alkyl groups having 4 to 6 carbon atoms since the compound exhibits solubility while maintaining high crystallinity, and exhibits high mobility. Moreover, it is expected that the compound exhibits improved heat resistance. It is still more preferable that R₂ and R₅ may be independently linear alkyl groups having 8 to 11 carbon atoms since the compound exhibits high solubility, and may suitably be used for a coating process. R₂ and R₅ may be independently a linear alkyl group having 5 to 11 carbon atoms.

As for R₁ to R₆ in the formula (1), it is also more preferable that R₁, R₂, R₄, and R₅ may be hydrogen atoms, and R₃ and R₆ in the formula (1) be independently a linear alkyl group having 3 to 20 carbon atoms or a branched alkyl group having 3 to 40 carbon atoms. It is still more preferable that R₃ and R₆ may be independently linear alkyl groups having 4 to 12 carbon atoms since the compound exhibits solubility while maintaining high crystallinity, and exhibits high mobility. Moreover, the compound may suitably be used for a coating process. R₃ and R₆ may be independently linear alkyl groups having 5 to 12 carbon atoms.

It is also more preferable that R₂, R₃, R₅, and R₆ in the formula (1) may be hydrogen atoms, and R₁ and R₄ in the formula (1) may be independently linear alkyl groups having 3 to 20 carbon atoms or a branched alkyl group having 3 to 40 carbon atoms. R₁ and R₄ may be independently linear alkyl groups having 4 to 12, or 6 to 10, or 8 carbon atoms.

Another organic semiconductor material according to the invention is a compound represented by the following formula (5).

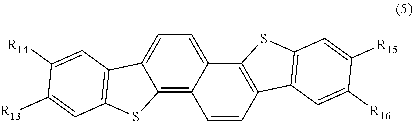

wherein R₁₃, R₁₄, R₁₅, and R₁₆ are independently linear alkyl groups having 3 to 11 carbon atoms or a branched alkyl group having 3 to 40 carbon atoms.

Examples of the linear alkyl group represented by R₁ to R₆ and R₁₃ to R₁₆ include an n-propyl group, an n-butyl group, an n-pentyl group, an n-hexyl group, an n-heptyl group, an n-octyl group, an n-nonyl group, an n-decyl group, an n-undecyl group, an n-dodecyl group, an n-tridecyl group, an n-tetradecyl group, an n-pentadecyl group, an n-hexadecyl group, an n-heptadecyl group, an n-octadecyl group, an n-nonadecyl group, an n-icosanyl group, and the like.

Examples of the branched alkyl group represented by R₁ to R₆ and R₁₃ to R₁₆ include an isopropyl group, an s-butyl group, an isobutyl group, a t-butyl group, a 2-ethylbutyl group, a 2-propylpentyl group, a 3-ethylpentyl group, a 4-propylheptyl group, a 5-ethylheptyl group, a 5-propyloctyl group, a 6-methylheptyl group, a 6-ethyloctyl group, a 6-propylnonyl group, a 7-methyloctyl group, a 7-ethylnonyl group, a 6-propyldecyl group, and the like.

Specific examples of the organic semiconductor materials according to the invention are shown below. Note that the organic semiconductor materials according to the invention are not limited to the following specific examples.

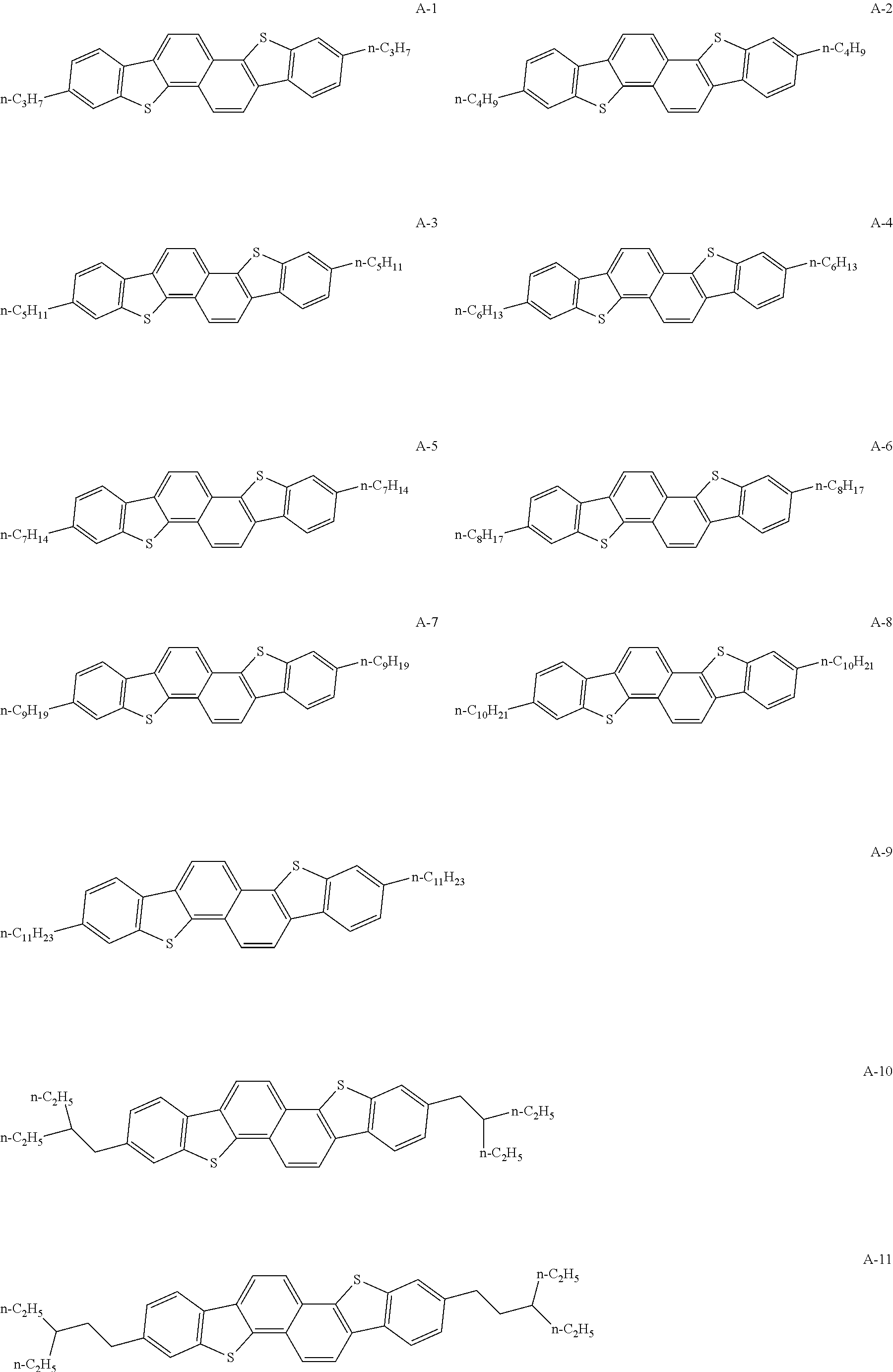

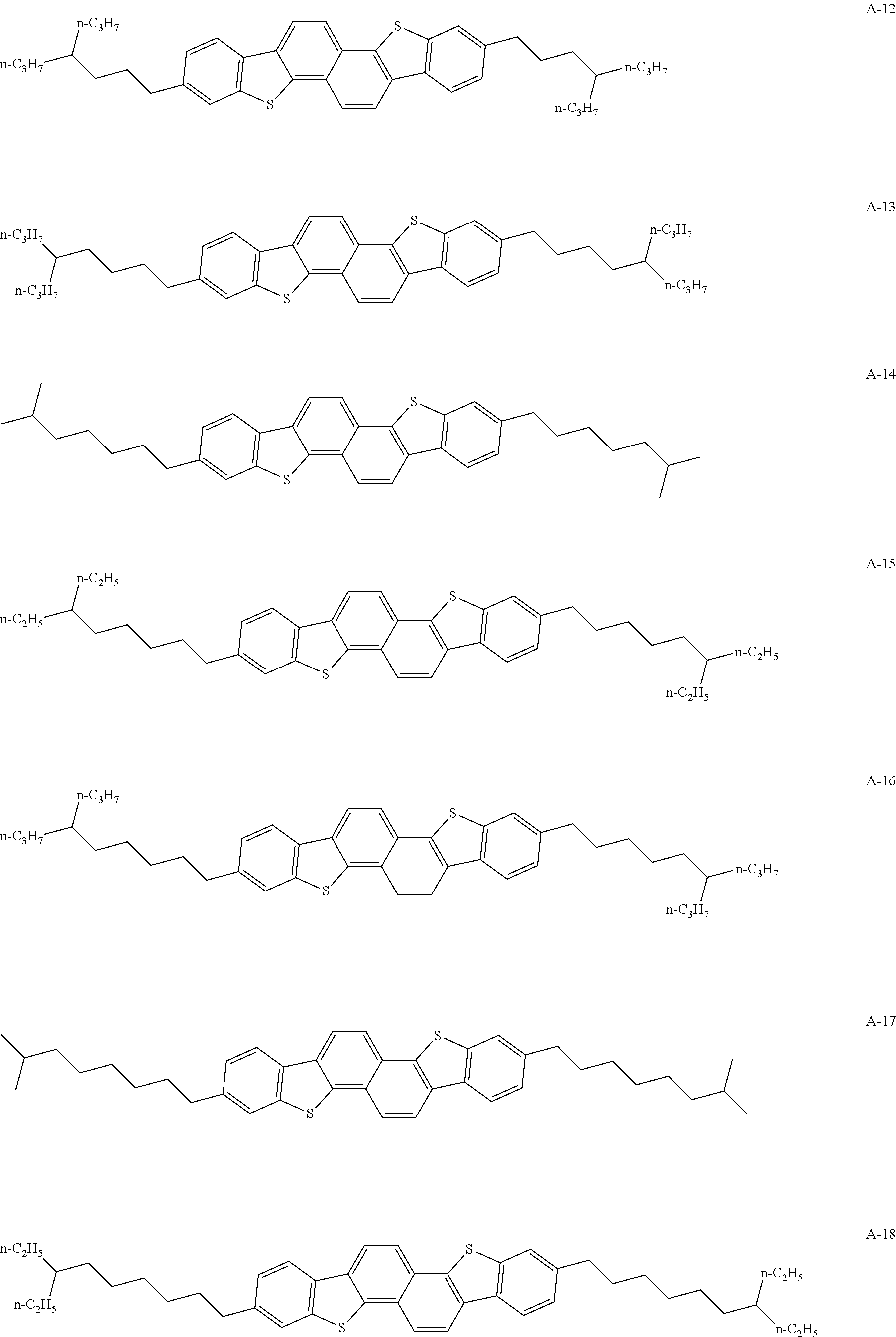

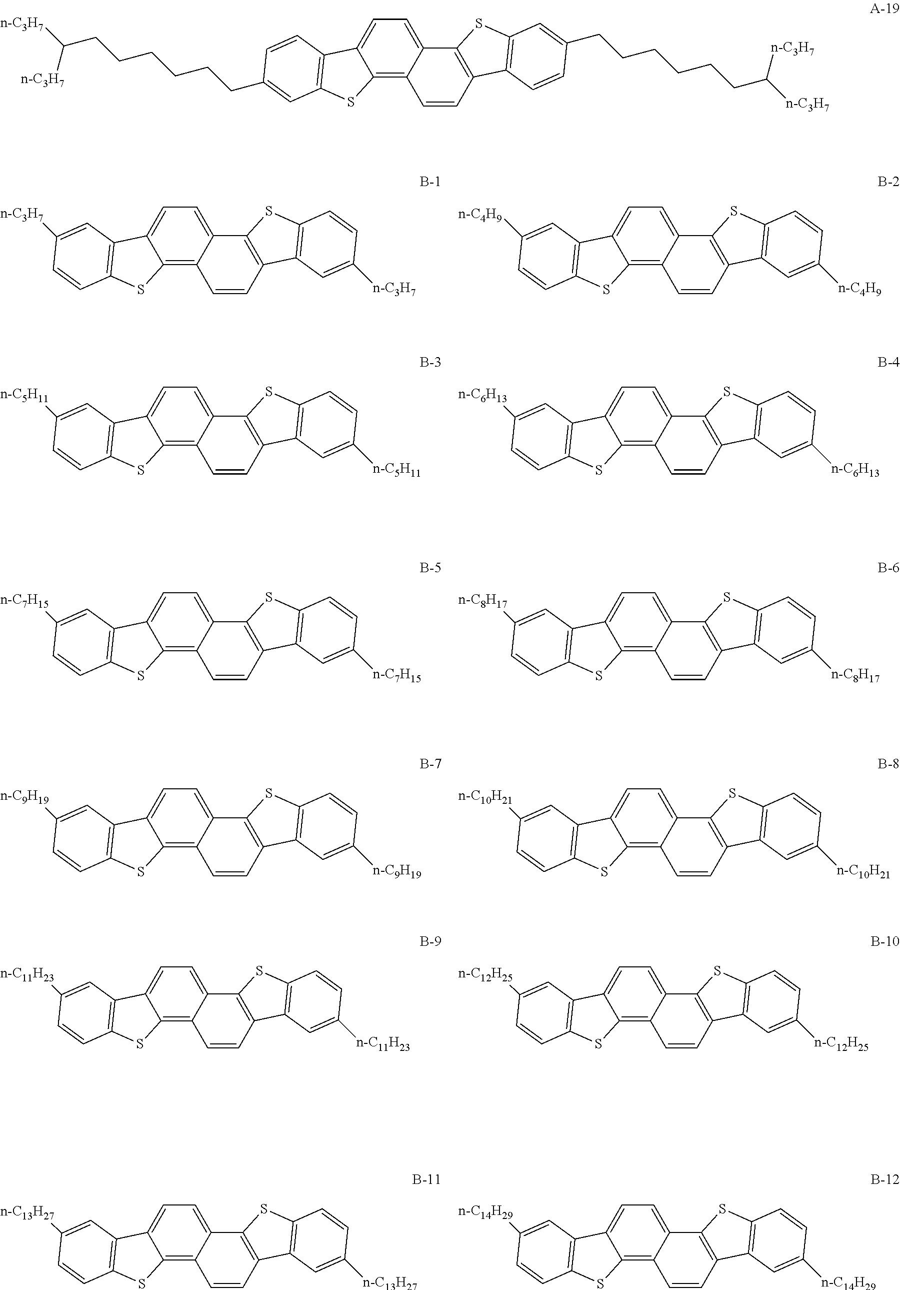

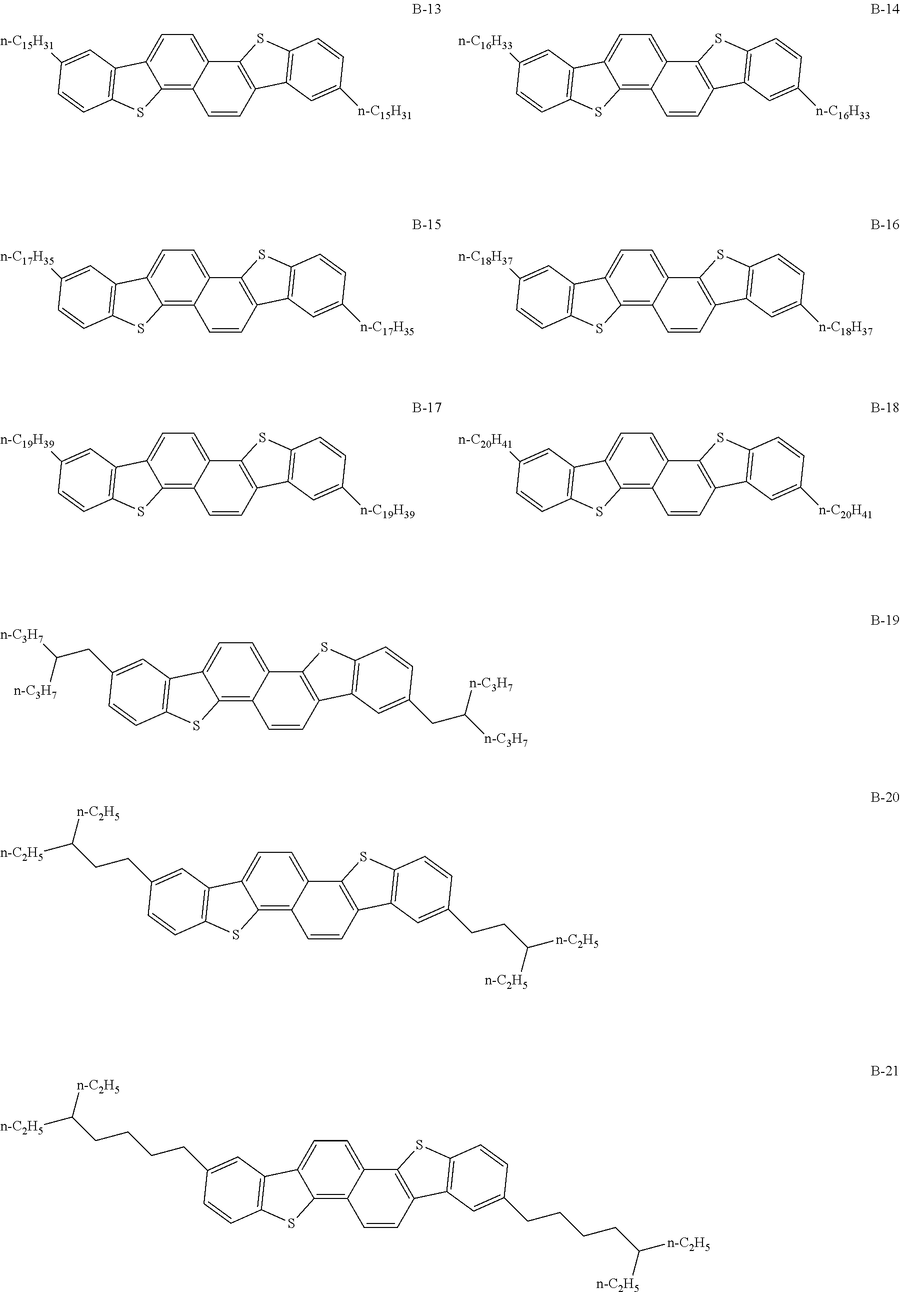

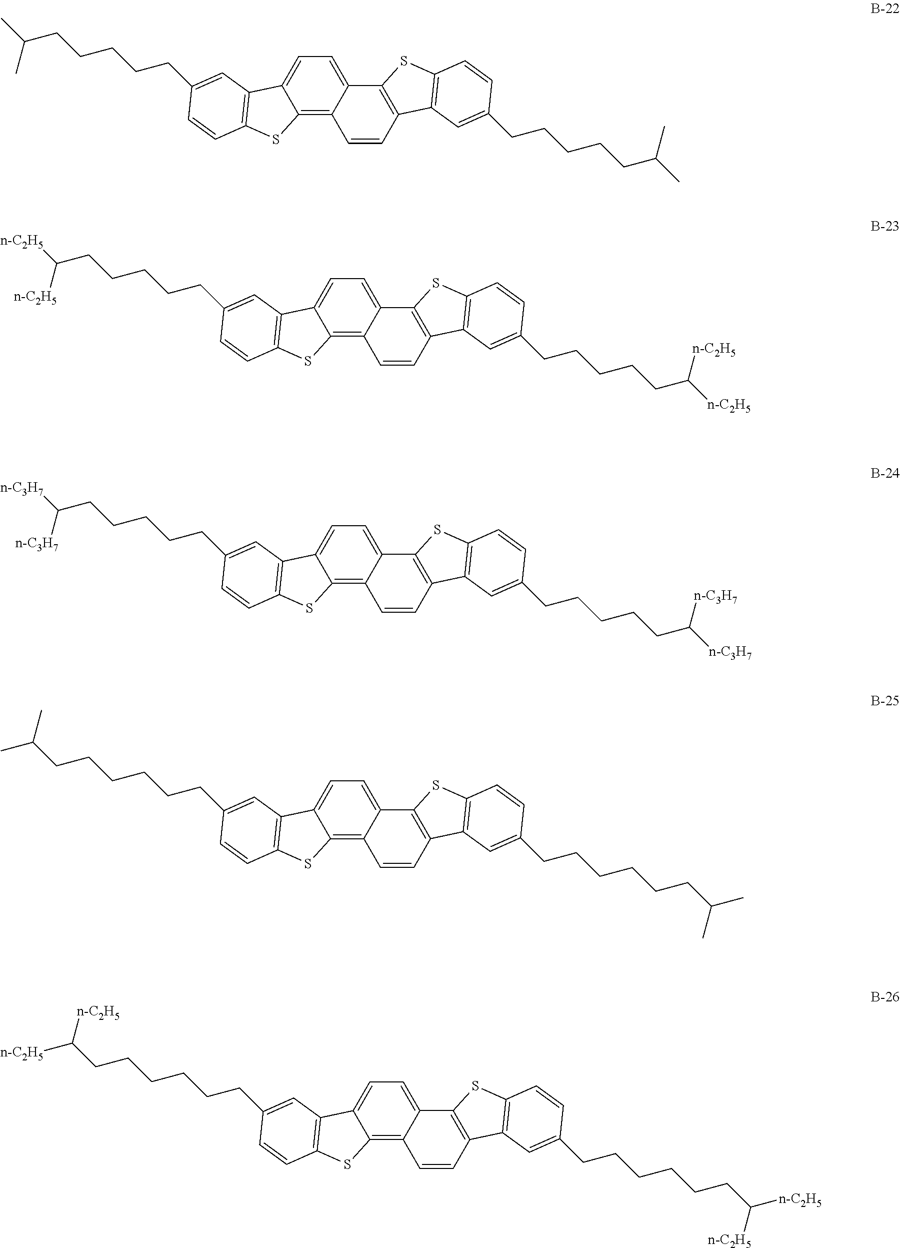

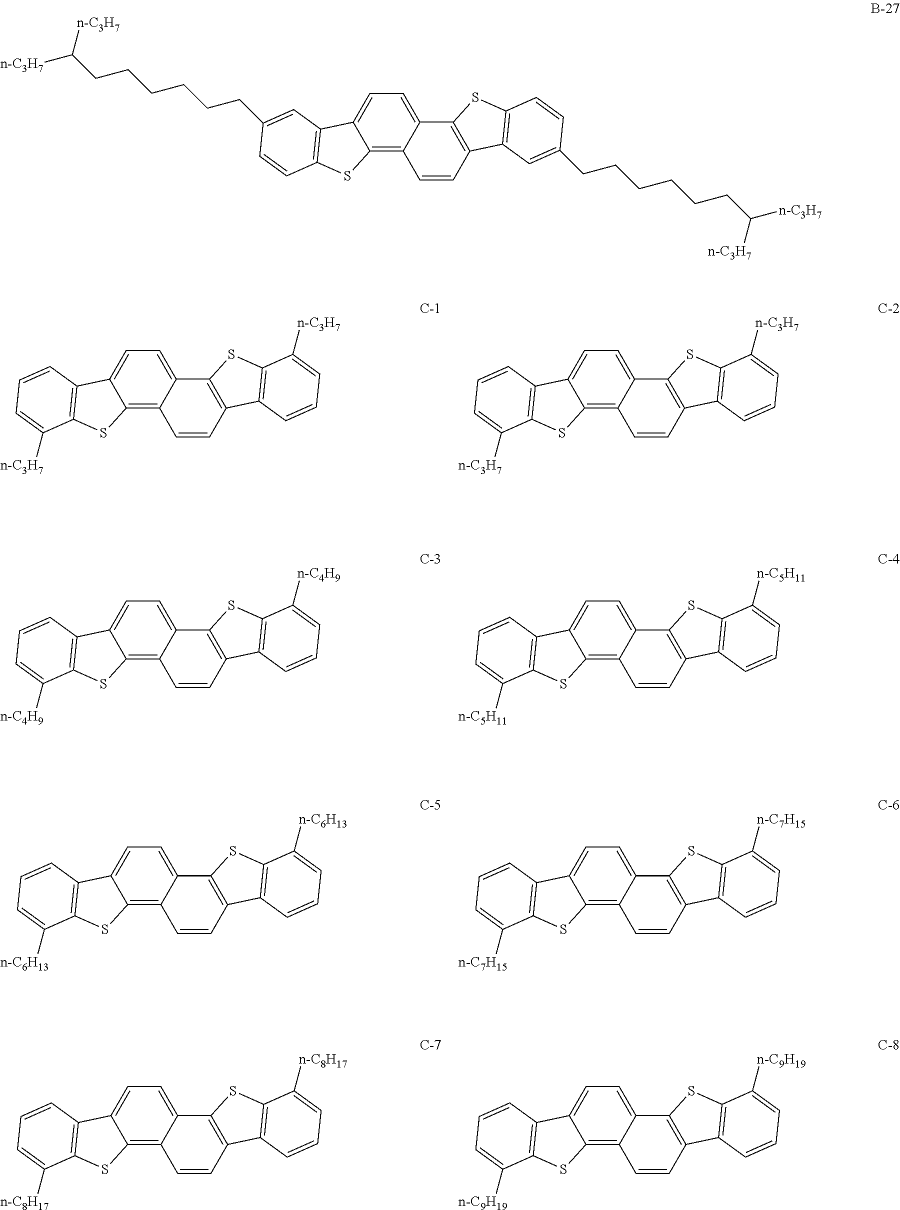

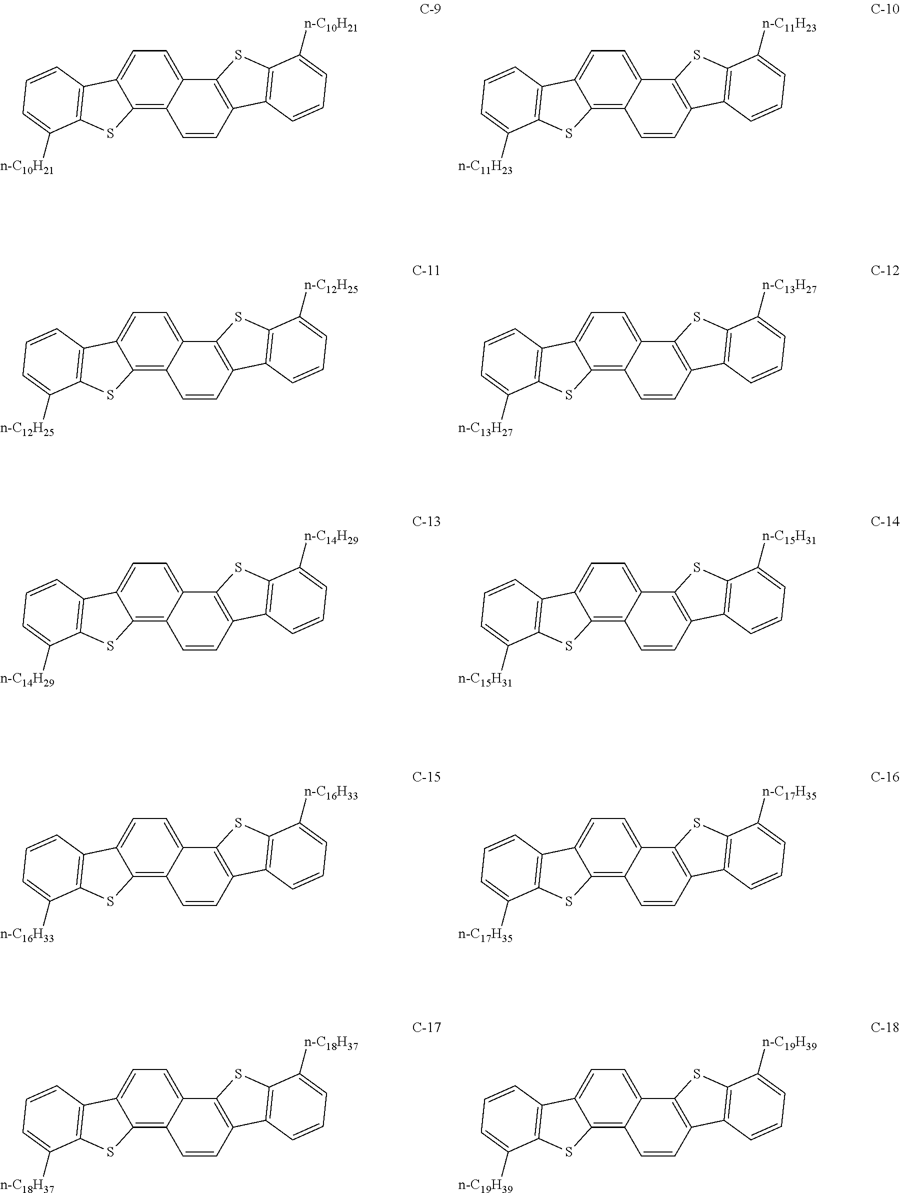

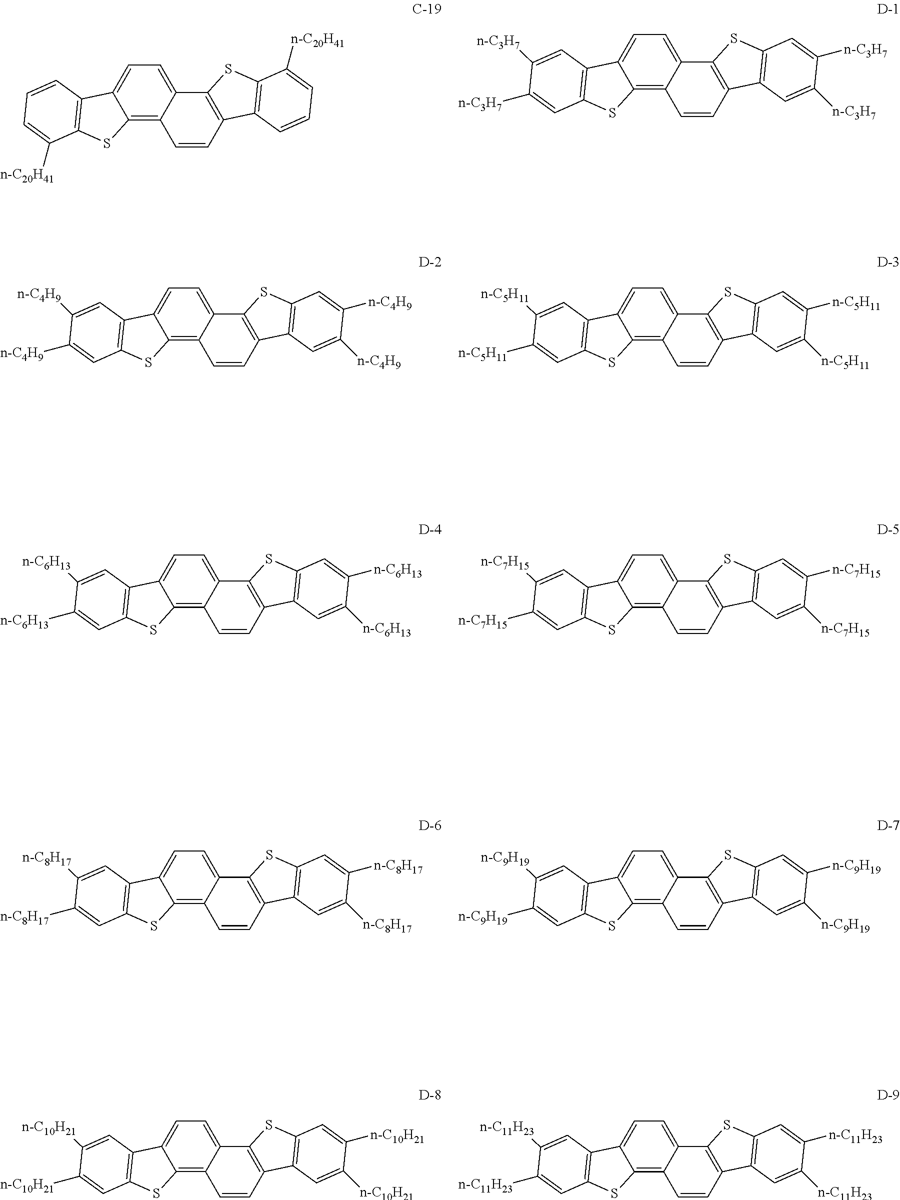

The organic semiconductor materials according to the invention may be synthesized by the Kumada-Tamao-Corriu coupling reaction (see (A)), a boronic acid synthesis reaction (see (B)), a bromination reaction (see (C)), the Suzuki-Miyaura coupling reaction (see (D)), and a cyclization reaction (see (E)).

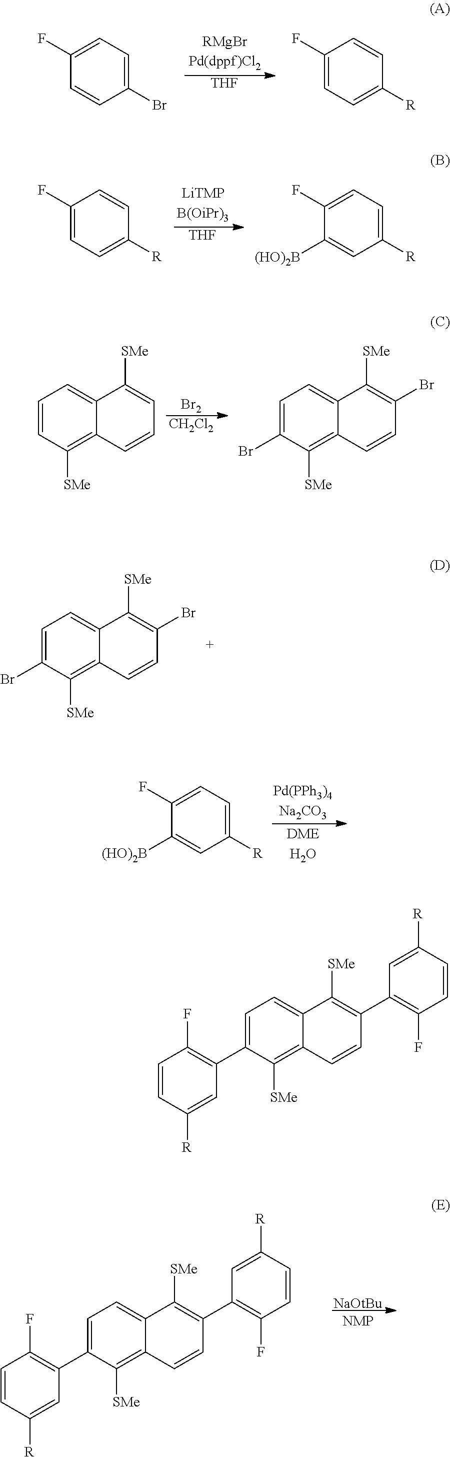

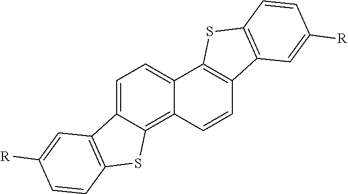

Note that an electronic device (e.g., transistor) that exhibits high field-effect mobility and a high ON/OFF ratio can be obtained by utilizing a material having high purity. Therefore, it is desirable to optionally purify the material by column chromatography, recrystallization, distillation, sublimation, or the like. The purity of the material can be improved by repeating these purification methods, or combining these purification methods. It is desirable to repeat purification by sublimation at least twice as the final purification step. It is preferable to use a material having a purity determined by HPLC of 90% or more. It is possible to increase the field-effect mobility and the ON/OFF ratio of an organic thin film transistor, and bring out the performance of the material when the material preferably has a purity of 95% or more (particularly preferably 99% or more).

The organic semiconductor material according to the invention may be used as a coating material, or may be used as a deposition material.

### Coating Liquid

A coating liquid according to the invention includes the organic semiconductor material according to the invention and an organic solvent.

The coating liquid according to the invention may be prepared by mixing the organic semiconductor material and the organic solvent, and heating the solvent up to a minimum temperature required to effect dissolution, for example.

The type of the organic solvent and the concentration of the coating liquid may be appropriately set as long as the object of the invention is not impaired. Examples of the organic solvent and the concentration of the coating liquid are given below.

Examples of the organic solvent include ketone-based solvents such as acetone, methyl ethyl ketone, methyl isobutyl ketone, cyclohexanone, and N-methyl-2-pyrrolidone (NMP); ester-based solvents such as ethyl acetate, butyl acetate, and γ-butyrolactone; ether-based solvents such as diethyl ether, dioxane, tetrahydrofuran (THF), and anisole; aromatic hydrocarbon solvents such as benzene, toluene, xylene, ethylbenzene, tetralin, and indan; aromatic halogenated hydrocarbon solvents such as 1,2,4-trichlorobenzene and o-dichlorobenzene; halogenated hydrocarbon solvents such as 1,2-dichloroethane, 1,1,2,2-tetrachloroethane, chloroform, and dichloromethane; sulfoxide-based solvents such as dimethyl sulfoxide (DMSO); and the like. These organic solvents may be used in combination.

The concentration of the organic semiconductor material in the coating liquid is 0.1 to 10 mass %, for example. The concentration of the organic semiconductor material in the coating liquid is preferably 0.4 mass % or more for the reasons described later.

The coating liquid according to the invention may further include a known organic semiconductor material (e.g., pentacene and thiophene oligomer) as long as the advantageous effects of the invention are not impaired.

### Organic Thin Film Transistor

The device configuration of an organic thin film transistor according to the invention is described below.

The organic thin film transistor according to the invention includes at least a gate electrode, a source electrode, a drain electrode, an insulator layer, and an organic semiconductor layer, and is configured so that the source-drain current is controlled by applying a voltage to the gate electrode. The organic semiconductor layer includes the organic semiconductor material according to the invention.

The structure of the transistor is not particularly limited. The elements other than the organic semiconductor layer may have a known device configuration. Specific examples of the device configuration of the organic thin film transistor are described below with reference to the drawings.

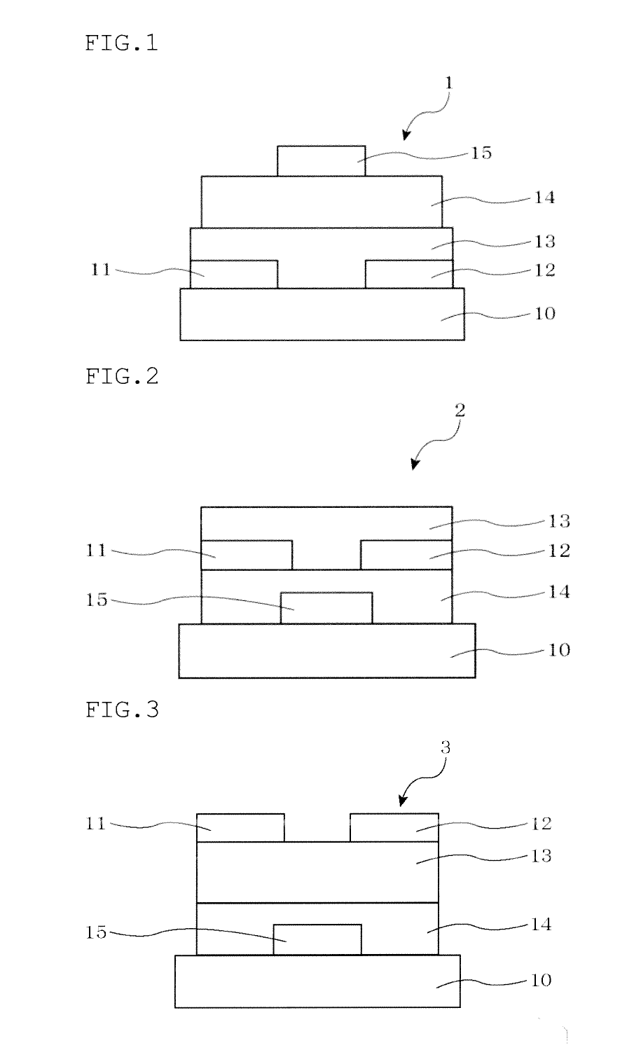

FIGS. 1 to 4 are views illustrating examples of the device configuration of the organic thin film transistor according to the invention.

An organic thin film transistor 1 illustrated in FIG. 1 has a configuration in which a source electrode 11 and a drain electrode 12 are formed on a substrate 10 at a given interval from each other. An organic semiconductor layer 13 is formed to cover the source electrode 11, the drain electrode 12, and the space between the source electrode 11 and the drain electrode 12, and an insulator layer 14 is stacked on the organic semiconductor layer 13. A gate electrode 15 is formed on the insulator layer 14 at a position over the space between the source electrode 11 and the drain electrode 12.

An organic thin film transistor 2 illustrated in FIG. 2 has a configuration in which a gate electrode 15 and an insulator layer 14 are sequentially formed on a substrate 10. A source electrode 11 and a drain electrode 12 are formed on the insulator layer 14 at a given interval from each other, and an organic semiconductor layer 13 is formed thereon. The organic semiconductor layer 13 forms a channel region. An ON/OFF operation is implemented by controlling a current that flows between the source electrode 11 and the drain electrode 12 by applying a voltage to the gate electrode 15.

An organic thin film transistor 3 illustrated in FIG. 3 has a configuration in which a gate electrode 15, an insulator layer 14, and an organic semiconductor layer 13 are sequentially formed on a substrate 10. A source electrode 11 and a drain electrode 12 are formed on the organic semiconductor layer 13 at a given interval from each other.

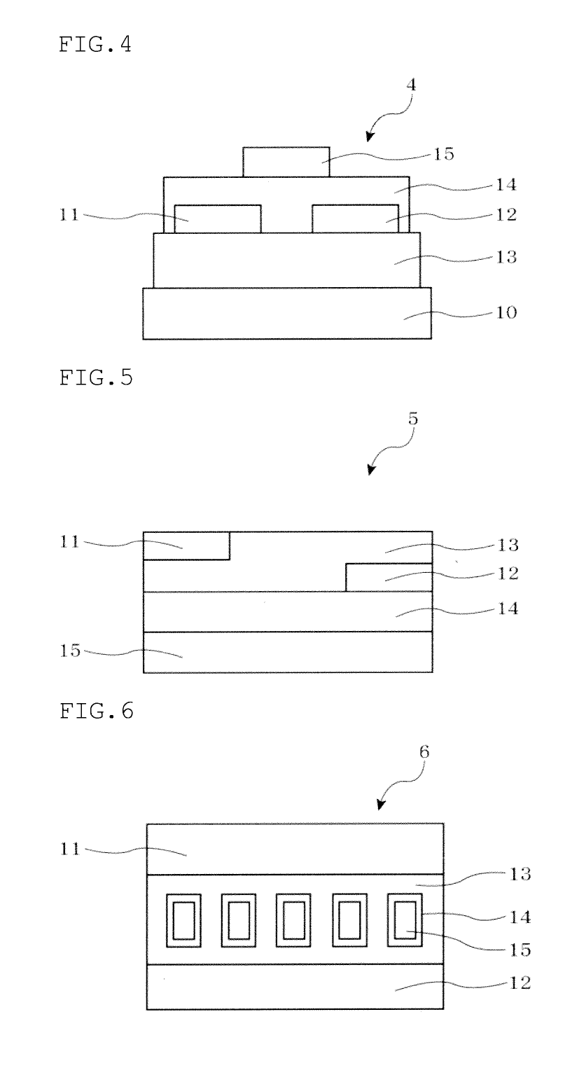

An organic thin film transistor 4 illustrated in FIG. 4 has a configuration in which an organic semiconductor layer 13 is formed on a substrate 10. A source electrode 11 and a drain electrode 12 are formed on the organic semiconductor layer 13 at a given interval from each other. An insulator layer 14 and a gate electrode 15 are sequentially formed thereon.

The organic thin film transistor according to the invention has a field effect transistor (FET) structure. The configuration of the organic thin film transistor depends on the position of each electrode, the layer stacking order, and the like. The organic thin film transistor includes an organic semiconductor layer (organic compound layer), a source electrode, a drain electrode, and a gate electrode, the source electrode and the drain electrode being formed at a given interval from each other, the gate electrode being formed at a given distance from the source electrode and the drain electrode, and a current that flows between the source electrode and the drain electrode being controlled by applying a voltage to the gate electrode. The interval between the source electrode and the drain electrode is determined depending on the application of the organic thin film transistor according to the invention. The interval between the source electrode and the drain electrode is normally about 0.1 μm to about 1 mm.

The device configuration of the organic thin film transistor according to the invention is not particularly limited as long as an ON/OFF operation, an amplification effect, and the like are implemented by controlling a current that flows between the source electrode and the drain electrode by applying a voltage to the gate electrode.

For example, the organic thin film transistor according to the invention may have the device configuration of a top and bottom contact organic thin film transistor 5 (see FIG. 5) proposed by Yoshida et al. (National Institute of Advanced Industrial Science and Technology) (see The Proceedings of the Meeting of the Japan Society of Applied Physics and Related Societies, 49th Spring Meeting, 27a-M-3 (March 2002), or the device configuration of a vertical organic thin film transistor 6 (see FIG. 6) proposed by Kudo et al. (Chiba University) (see Transactions of the Institute of Electrical Engineers of Japan, 118-A (1998), p. 1440).

Each constituent member of the organic thin film transistor is described below.

### Organic Semiconductor Layer

The organic semiconductor layer included in the organic thin film transistor according to the invention includes the organic semiconductor material according to the invention. It is important that the organic semiconductor layer be a continuous crystalline film having a continuous conducting path. It is preferable that the organic semiconductor layer be a film that is formed using the coating liquid according to the invention while appropriately selecting the coating method, the coating solvent, the concentration of the material in the coating solvent, and the like in order to obtain a film having continuity. For example, when forming the organic semiconductor layer by spin coating using toluene as the solvent, a film having continuity can be easily obtained when the concentration of the organic semiconductor material according to the invention is 0.4 mass % or more.

The coating method used when forming the organic semiconductor layer is not particularly limited. A known coating method may be used. For example, the organic semiconductor layer may be formed using the organic semiconductor layer material by molecular beam epitaxy (MBE), vacuum deposition, chemical vapor deposition, dipping (that uses a solution prepared by dissolving the material in a solvent), spin coating, casting, bar coating, roll coating, printing (e.g., inkjet method), coating/baking, electropolymerization, molecular beam deposition, self-assembly from a solution, or a combination thereof.

Since the field-effect mobility is improved by improving the crystallinity of the organic semiconductor layer, it is preferable to anneal the film regardless of the film-forming method in order to obtain a high-performance device. The annealing temperature is preferably 50 to 200° C., and more preferably 70 to 200° C. The annealing time is preferably 10 minutes to 12 hours, and more preferably 1 to 10 hours.

The organic semiconductor layer may be formed using one type of the compound represented by the formula (1) or (5), or may be formed using a plurality of types of the compound represented by the formula (1) or (5), or may be formed as a mixed thin film or a laminate using a known semiconductor (e.g., pentacene or thiophene oligomer).

### Substrate

The substrate included in the organic thin film transistor according to the invention supports the organic thin film transistor structure. A glass substrate, a substrate formed of an inorganic compound (e.g., metal oxide or nitride), a plastic film (PET, PES, or PC), a metal substrate, a composite thereof, a laminate thereof, or the like may be used as the substrate. The substrate may not be used when the organic thin film transistor structure can be sufficiently supported by an element other than the substrate. A silicon (Si) wafer is normally used as the substrate. In this case, the Si wafer may be used as the gate electrode and the substrate. The surface of the Si wafer may be oxidized to form SiO₂, which may be used as an insulating layer. In this case, a metal layer (e.g., Au layer) may be formed on the Si substrate (that serves as the substrate and the gate electrode) as a lead wire connection electrode.

### Electrode

A material for forming the gate electrode, the source electrode, and the drain electrode included in the organic thin film transistor according to the invention is not particularly limited as long as the material is a conductive material. Examples of the material for forming the gate electrode, the source electrode, and the drain electrode include platinum, gold, silver, nickel, chromium, copper, iron, tin, antimony, lead, tantalum, indium, palladium, tellurium, rhenium, iridium, aluminum, ruthenium, germanium, molybdenum, tungsten, antimony tin oxide, indium tin oxide (ITO), fluorine-doped zinc oxide, zinc, carbon, graphite, glassy carbon, a silver paste, a carbon paste, lithium, beryllium, sodium, magnesium, potassium, calcium, scandium, titanium, manganese, zirconium, gallium, niobium, a sodium-potassium alloy, a magnesium/copper mixture, a magnesium/silver mixture, a magnesium/aluminum mixture, a magnesium/indium mixture, an aluminum/aluminum oxide mixture, a lithium/aluminum mixture, and the like.

The electrode may be formed by deposition, electron beam deposition, sputtering, an atmospheric pressure plasma method, ion plating, chemical vapor deposition, electrodeposition, electroless plating, spin coating, printing, an inkjet method, or the like. The electrode may optionally be patterned by a method that subjects a conductive thin film formed by the above method to a known photolithographic technique or a lift-off technique to form an electrode, a method that forms a resist on a metal foil (e.g., aluminum foil or copper foil) by a thermal transfer method, an inkjet method, or the like, and etches the metal foil, or the like.

The thickness of the electrode is not particularly limited as long as a current flows through the electrode, but is preferably 0.2 nm to 10 μm, and more preferably 4 to 300 nm. When the thickness of the electrode is within the above preferable range, it is possible to prevent a situation in which a voltage drop occurs due to an increase in resistance. It is also possible to form a film within a short time, and smoothly form a stacked film due to the absence of a difference in level when stacking an additional layer (e.g., protective layer or organic semiconductor layer).

The source electrode, the drain electrode, and the gate electrode included in the organic thin film transistor according to the invention may be formed using a fluid electrode material (e.g., solution, paste, ink, or dispersion) that includes the above conductive material. It is preferable to form the source electrode, the drain electrode, and the gate electrode using a fluid electrode material that includes a conductive polymer or metal particles that include platinum, gold, silver, or copper. It is preferable to use a solvent or a dispersion medium having a water content of 60 mass % or more (preferably 90 mass % or more) in order to suppress damage to the organic semiconductor. A known conductive paste or the like may be used as the dispersion that includes metal particles. It is preferable that the dispersion include metal particles having a particle size of 0.5 to 50 nm or 1 to 10 nm. Examples of a material for forming the metal particles include platinum, gold, silver, nickel, chromium, copper, iron, tin, antimony, lead, tantalum, indium, palladium, tellurium, rhenium, iridium, aluminum, ruthenium, germanium, molybdenum, tungsten, zinc, and the like. It is preferable to form the electrode using a dispersion prepared by dispersing the metal particles in a dispersion medium (e.g., water or common organic solvent) using a dispersion stabilizer (e.g., organic material). The metal particle dispersion may be prepared by a physical method (e.g., gas evaporation method, sputtering method, or metal vapor synthesis method) or a chemical method (e.g. colloidal method or co-precipitation method) that reduces metal ions in a liquid phase to produce metal particles. It is preferable to prepare the metal particle dispersion by the colloidal method described in JP-A-11-76800, JP-A-11-80647, JP-A-11-319538, JP-A-2000-239853, or the like, or the gas evaporation method described in JP-A-2001-254185, JP-A-2001-53028, JP-A-2001-35255, JP-A-2000-124157, JP-A-2000-123634, or the like.

An electrode pattern may be formed directly by an inkjet method using the metal particle dispersion, or may be formed from a coating film by lithography, laser ablation, or the like. An electrode pattern may also be formed by a printing method (e.g., relief printing, intaglio printing, planographic printing, or screen printing). An electrode pattern having the desired shape may be formed by forming an electrode, drying the solvent, and optionally heating the electrode at 100 to 300° C. (preferably 150 to 200° C.) in a pattern to thermally bond the metal particles.

It is also preferable to form the gate electrode, the source electrode, and the drain electrode using a known conductive polymer for which conductivity is increased by doping or the like. For example, conductive polyaniline, conductive polypyrrole, conductive polythiophene, a polyethylenedioxythiophene (PEDOT)-polystyrenesulfonic acid complex, or the like may preferably be used. The contact resistance of the source electrode and the drain electrode with the organic semiconductor layer can be reduced by utilizing these materials. In this case, an electrode pattern may be formed directly by an inkjet method, or may be formed from a coating film by lithography, laser ablation, or the like. An electrode pattern may also be formed by a printing method (e.g., relief printing, intaglio printing, planographic printing, or screen printing).

It is preferable to form the source electrode and the drain electrode using a material among the above materials that exhibits low electrical resistance at the contact surface with the organic semiconductor layer. The electrical resistance of the material corresponds to the field-effect mobility when producing a current control device, and must be as low as possible in order to obtain high mobility. This normally depends on the relationship between the work function of the electrode material and the energy level of the organic semiconductor layer.

When the work function (W) of the electrode material is referred to as “a”, the ionization potential (Ip) of the organic semiconductor layer is referred to as “b”, and the electron affinity (Af) of the organic semiconductor layer is referred to as “c”, it is preferable that the following relational expression be satisfied. Note that a, b, and c are positive values based on the vacuum level.

When producing a p-type organic thin film transistor, it is preferable that “b-a<1.5 eV” (expression (I)) (more preferably “b-a<1.0 eV”) be satisfied. A high-performance device can be obtained when the above relationship with the organic semiconductor layer can be maintained. It is preferable to select an electrode material having as large a work function as possible. It is preferable to use an electrode material having a work function of 4.0 eV or more, and more preferably 4.2 eV or more. A metal having a large work function may be selected from the metals having a work function of 4.0 eV or more listed in Kagaku Binran (Handbook of Chemistry) Kiso-hen II (3rd Edition, edited by the Chemical Society of Japan, Maruzen Co., Ltd., 1983, p. 493), for example. Examples of a metal having a large work function include Ag (4.26, 4.52, 4.64, 4.74 eV), Al (4.06, 4.24, 4.41 eV), Au (5.1, 5.37, 5.47 eV), Be (4.98 eV), Bi (4.34 eV), Cd (4.08 eV), Co (5.0 eV), Cu (4.65 eV), Fe (4.5, 4.67, 4.81 eV), Ga (4.3 eV), Hg (4.4 eV), Ir (5.42, 5.76 eV), Mn (4.1 eV), Mo (4.53, 4.55, 4.95 eV), Nb (4.02, 4.36, 4.87 eV), Ni (5.04, 5.22, 5.35 eV), Os (5.93 eV), Pb (4.25 eV), Pt (5.64 eV), Pd (5.55 eV), Re (4.72 eV), Ru (4.71 eV), Sb (4.55, 4.7 eV), Sn (4.42 eV), Ta (4.0, 4.15, 4.8 eV), Ti (4.33 eV), V (4.3 eV), W (4.47, 4.63, 5.25 eV), Zr (4.05 eV), and the like.

Among these, noble metals (Ag, Au, Cu, and Pt), Ni, Co, Os, Fe, Ga, Ir, Mn, Mo, Pd, Re, Ru, V, and W are preferable. ITO, a conductive polymer (e.g., polyaniline and PEDOT:PSS), and carbon are preferable as an electrode material other than a metal. The electrode material may include only one type of material having a large work function, or may include two or more types of material having a large work function, as long as the work function of the electrode material satisfies the expression (I).

When producing an n-type organic thin film transistor, it is preferable that “a-c<1.5 eV” (expression (II)) (more preferably “a-c<1.0 eV”) be satisfied. A high-performance device can be obtained when the above relationship with the organic semiconductor layer can be maintained. It is preferable to select an electrode material having as small a work function as possible. It is preferable to use an electrode material having a work function of 4.3 eV or less, and more preferably 3.7 eV or less.

A metal having a small work function may be selected from the metals having a work function of 4.3 eV or less listed in Kagaku Binran (Handbook of Chemistry) Kiso-hen II (3rd Edition, edited by the Chemical Society of Japan, Maruzen Co., Ltd., 1983, p. 493), for example. Examples of a metal having a small work function include Ag (4.26 eV), Al (4.06, 4.28 eV), Ba (2.52 eV), Ca (2.9 eV), Ce (2.9 eV), Cs (1.95 eV), Er (2.97 eV), Eu (2.5 eV), Gd (3.1 eV), Hf (3.9 eV), In (4.09 eV), K (2.28 eV), La (3.5 eV), Li (2.93 eV), Mg (3.66 eV), Na (2.36 eV), Nd (3.2 eV), Rb (4.25 eV), Sc (3.5 eV), Sm (2.7 eV), Ta (4.0, 4.15 eV), Y (3.1 eV), Yb (2.6 eV), Zn (3.63 eV), and the like. Among these, Ba, Ca, Cs, Er, Eu, Gd, Hf, K, La, Li, Mg, Na, Nd, Rb, Y, Yb, and Zn are preferable. The electrode material may include only one type of material having a small work function, or may include two or more types of material having a small work function, as long as the work function of the electrode material satisfies the expression (II). Since a metal having a small work function easily deteriorates upon contact with moisture or oxygen in air, it is desirable to optionally coat a metal having a small work function with a metal that is stable in air (e.g., Ag or Au). The thickness of the coating must be 10 nm or more, and a metal having a small work function can be sufficiently protected from oxygen and moisture as the thickness of the coating increases. It is desirable to set the thickness of the coating to 1 μm or less from the viewpoint of productivity and the like.

### Buffer Layer

The organic thin film transistor according to the invention may include a buffer layer between the organic semiconductor layer and the source electrode/drain electrode in order to improve the injection efficiency, for example. It is desirable to form the buffer layer of an n-type organic thin film transistor using a compound that is used to form a cathode of an organic EL device and has an alkali metal/alkaline-earth metal ionic bond (e.g., LiF, Li₂O, CsF, Na₂CO₃, KCl, MgF₂, or CaCO₃). The buffer layer may also be formed using a compound that is used to form an electron-injecting layer and an electron-transporting layer of an organic EL device (e.g., Alq).

It is desirable to form the buffer layer of a p-type organic thin film transistor using FeCl₃, a cyano compound (e.g., TCNQ, F4-TCNQ, or HAT), CFₓ, a metal oxide other than alkali metal/alkaline-earth metal oxides (e.g., GeO₂, SiO₂, MoO₃, V₂O₅, VO₂, V₂O₃, MnO, Mn₃O₄, ZrO₂, WO₃, TiO₂, In₂O₃, ZnO, NiO, HfO₂, Ta₂O₅, ReO₃, or PbO₂), or an inorganic compound (e.g., ZnS or ZnSe). These oxides tend to show oxygen vacancy that is suitable for hole injection. The buffer layer may also be formed using a compound that is used to form a hole-injecting layer and a hole-transporting layer of an organic EL device (e.g., amine compound (e g TPD or NPD) or CuPc). It is desirable to form the buffer layer using two or more compounds among these compounds.

It is known that the buffer layer decreases the threshold voltage by decreasing the carrier injection barrier, and makes it possible to drive the transistor at a low voltage. Specifically, a carrier trap is present at the interface between the organic semiconductor and the insulator layer, and carriers that are initially injected are used to fill the trap when the gate voltage is applied. The trap is filled at a low voltage, and the mobility is improved by inserting the buffer layer. It suffices that a thin buffer layer be present between the electrode and the organic semiconductor layer. The thickness of the buffer layer is normally 0.1 to 30 nm, and preferably 0.3 to 20 nm.

### Insulator Layer

A material for forming the insulator layer included in the organic thin film transistor according to the invention is not particularly limited as long as the material has electrical insulating properties and can form a thin film. The insulator layer may be formed using a material having an electrical resistivity of 10 ∩·cm or more at room temperature (e.g., metal oxide (including silicon oxide), metal nitride (including silicon nitride), polymer, or organic low-molecular-weight compound), and the like. An inorganic oxide film having a high relative dielectric constant is preferable as the insulator layer.

Examples of the inorganic oxide include silicon oxide, aluminum oxide, tantalum oxide, titanium oxide, tin oxide, vanadium oxide, barium strontium titanate, barium titanate zirconate, lead zirconate titanate, lead lanthanum titanate, strontium titanate, barium titanate, lanthanum oxide, fluorine oxide, magnesium oxide, bismuth oxide, bismuth titanate, niobium oxide, strontium bismuth titanate, strontium bismuth tantalate, tantalum pentoxide, bismuth niobate tantalate, yttrium trioxide, combinations thereof, and the like. Among these, silicon oxide, aluminum oxide, tantalum oxide, and titanium oxide are preferable.

An inorganic nitride such as silicon nitride (Si₃N₄, SiₓN_{y} (x and y>0)) or aluminum nitride may also preferably be used.

The insulator layer may be formed using a precursor that includes a metal alkoxide. For example, the insulator layer is formed by applying a solution of the precursor to a substrate to form a film, and subjecting the film to a chemical solution treatment including a heat treatment.

The metal that forms the metal alkoxide is selected from the transition metals, the lanthanoids, and the main-group elements. Specific examples of the metal that forms the metal alkoxide include barium (Ba), strontium (Sr), titanium (Ti), bismuth (Bi), tantalum (Ta), zirconium (Zr), iron (Fe), nickel (Ni), manganese (Mn), lead (Pb), lanthanum (La), lithium (Li), sodium (Na), potassium (K), rubidium (Rb), cesium (Cs), francium (Fr), beryllium (Be), magnesium (Mg), calcium (Ca), niobium (Nb), thallium (TI), mercury (Hg), copper (Cu), cobalt (Co), rhodium (Rh), scandium (Sc), yttrium (Y), and the like. Examples of the alkoxide that forms the metal alkoxide include alkoxides derived from alcohols such as methanol, ethanol, propanol, isopropanol, butanol, and isobutanol, alkoxyalcohols such as methoxyethanol, ethoxyethanol, propoxyethanol, butoxyethanol, pentoxyethanol, heptoxyethanol, methoxypropanol, ethoxypropanol, propoxypropanol, butoxypropanol, pentoxypropanol, and heptoxypropanol, and the like.

When the insulator layer is formed using the above material, polarization easily occurs in the insulator layer, and the threshold voltage of the transistor can be reduced. In particular, when the insulator layer is formed using silicon nitride (Si₃N₄, SiₓN_{y}, or SiONₓ (x and y>0), a depletion layer more easily occurs, and the threshold voltage of the transistor can be further reduced.

The insulator layer may be formed using an organic compound such as a polyimide, a polyamide, a polyester, a polyacrylate, a photocurable resin that undergoes photoradical polymerization or photocationic polymerization, a copolymer that includes an acrylonitrile component, polyvinylphenol, polyvinyl alcohol, a novolac resin, or cyanoethyl pullulan.

The insulator layer may also be formed using a polymer material having a high dielectric constant, such as wax, polyethylene, polychloropyrene, polyethylene terephthalate, polyoxymethylene, polyvinyl chloride, polyvinylidene fluoride, polysulfone, polyimide cyanoethyl pullulan, poly(vinylphenol) (PVP), poly(methyl methacrylate) (PMMA), polycarbonate (PC), polystyrene (PS), a polyolefin, polyacrylamide, poly(acrylic acid), a novolac resin, a resol resin, a polyimide, polyxylylene, an epoxy resin, or pullulan.

A material that exhibits water repellency is particularly preferable as the organic compound material and the polymer material used to form the insulator layer. It is possible to suppress interaction between the insulator layer and the organic semiconductor layer due to water repellency, and improve the crystallinity of the organic semiconductor layer by utilizing the aggregation properties of the organic semiconductor. As a result, the device performance can be improved. Examples of such a material include the polyparaxylylene derivatives described in Yasuda et al., Jpn. J. Appl. Phys., Vol. 42 (2003), pp. 6614-6618, and the materials described in Janos Veres et al., Chem. Mater., Vol. 16 (2004), pp. 4543-4555.

It is possible to form a film while reducing damage to the organic semiconductor layer by utilizing such an organic compound as the material for forming the insulator layer when employing the top gate structure illustrated in FIGS. 1 and 4.

The insulator layer may be a mixture layer that is formed using a plurality of inorganic or organic compound materials, or may be a multilayer structure of such layers. In this case, the performance of the device may be controlled by mixing or stacking a material that exhibits a high dielectric constant and a material that exhibits water repellency.

The insulator layer may be an anodic oxide film, or may include an anodic oxide film. It is preferable to subject the anodic oxide film to a sealing treatment. The anodic oxide film is formed by anodizing an anodizable metal using a known method. Examples of the anodizable metal include aluminum and tantalum. The anodizing method is not particularly limited, and may be implemented by a known method. An oxide film is formed by anodizing. An electrolyte solution used for anodizing is not particularly limited as long as a porous oxide film can be formed. Sulfuric acid, phosphoric acid, oxalic acid, chromic acid, boric acid, sulfamic acid, benzenesulfonic acid, a mixed acid of two or more of these acids, or a salt thereof is normally used as the electrolyte solution. The anodizing conditions differ depending on the electrolyte solution. The concentration of the electrolyte solution is normally 1 to 80 mass %, the temperature of the electrolyte solution is normally 5 to 70° C., the current density is normally 0.5 to 60 A/cm², the voltage is normally 1 to 100 V, and the electrolysis time is normally 10 seconds to 5 minutes. It is preferable to perform anodizing an aqueous solution of sulfuric acid, phosphoric acid, or boric acid as the electrolyte solution, and applying a direct current. Note that an alternating current may also be used. The acid concentration is preferably 5 to 45 mass %. It is preferable to perform the electrolysis treatment at an electrolyte solution temperature of 20 to 50° C. and a current density of 0.5 to 20 A/cm² for 20 to 250 seconds.

When the thickness of the insulator layer is small, the root-mean-square voltage applied to the organic semiconductor increases, and the driving voltage and the threshold voltage of the device can be reduced. On the other hand, a source-gate leakage current increases when the thickness of the insulator layer is small. Therefore, it is necessary to appropriately select the thickness of the insulator layer. The thickness of the insulator layer is normally 10 nm to 5 μm, preferably 50 nm to 2 μm, and more preferably 100 nm to 1 μm.

An arbitrary orientation treatment may be provided between the insulator layer and the organic semiconductor layer. For example, it is preferable to subject the surface of the insulator layer to a water-repellent treatment or the like to reduce interaction between the insulator layer and the organic semiconductor layer, and improve the crystallinity of the organic semiconductor layer. More specifically, the surface of the insulating film may be brought into contact with a silane coupling agent (e.g., hexamethyldisilazane, octadecyltrichlorosilane, or trichloromethylsilazane) or a self-assembling oriented film material (e.g., alkanephosphoric acid, alkanesulfonic acid, or alkanecarboxylic acid) in a liquid phase or a gas phase to form a self-assembled film, and the self-assembled film is moderately dried. It is also preferable to form a polyimide film or the like on the surface of the insulating film, and subject the surface of the polyimide film or the like to a rubbing treatment (e.g., liquid crystal alignment treatment).

The insulator layer may be formed by a dry process (e.g., vacuum deposition, molecular beam epitaxy, ion cluster beam technique, low-energy ion beam technique, ion plating, CVD, sputtering, or atmospheric pressure plasma method (see JP-A-11-61406, JP-A-11-133205, JP-A-2000-121804, JP-A-2000-147209, and JP-A-2000-185362)), or a wet process (e.g., coating method (e.g., spray coating, spin coating, blade coating, dip coating, casting, roll coating, bar coating, or die coating) or patterning method that utilizes printing or an inkjet method). These methods may be appropriately used depending on the material. The wet process may be implemented by utilizing a method that applies a liquid prepared by dispersing inorganic oxide fine particles in an arbitrary organic solvent or water optionally using a dispersion assistant (e.g., surfactant), and dries the applied liquid, or a sol-gel method that applies a solution of an oxide precursor (e.g., alkoxide), and dries the applied solution.

The organic thin film transistor according to the invention may be produced by any known method. It is preferable to perform a transistor production process (i.e., substrate placement, gate electrode formation, insulator layer formation, organic semiconductor layer formation, source electrode formation, and drain electrode formation) while preventing contact with air in order to prevent a deterioration in device performance due to moisture, oxygen, and the like upon contact with air. When contact with air is inevitable, it is preferable to prevent contact with air after forming the organic semiconductor layer, and clean/activate the exposed surface by UV irradiation, UV/ozone irradiation, oxygen plasma, argon plasma, or the like immediately before forming the organic semiconductor layer. Note that the performance of a certain p-type TFT material is improved due to adsorption of oxygen or the like upon contact with air. It is preferable to appropriately bring such a material into contact with air.

A gas barrier layer may be formed on the entirety or part of the outer circumferential surface of the organic transistor device taking account of the effects of oxygen, water, and the like contained in air on the organic semiconductor layer. The gas barrier layer may be formed using a material commonly used in the art. For example, the gas barrier layer may be formed using polyvinyl alcohol, an ethylene-vinyl alcohol copolymer polyvinyl chloride, polyvinylidene chloride, polychlorotrifluoroethylene, or the like. An insulating inorganic material mentioned above in connection with the insulator layer may also be used.

The invention may provide an organic thin film transistor that emits light by utilizing a current that flows between the source electrode and the drain electrode, and is configured so that emission of light is controlled by applying a voltage to the gate electrode. Specifically, the organic thin film transistor may be used as an emitting device (organic EL device). According to the invention, since a transistor for controlling emission of light and an emitting device can be integrated, it is possible to implement a reduction in cost via an increase in aperture ratio of the display and simplification of the production process. Therefore, significant practical advantages can be achieved. When using the organic thin film transistor as an organic light-emitting transistor, it is necessary to inject holes from one of the source electrode and the drain electrode, to inject electrons from the other of the source electrode and the drain electrode, respectively. It is preferable to satisfy the following conditions in order to improve the emission performance.

It is preferable that at least one of the source electrode and the drain electrode of the organic thin film light-emitting transistor according to the invention be a hole-injecting electrode in order to improve the hole injection capability. The hole-injecting electrode is an electrode that includes a material having a work function of 4.2 eV or more.

It is also preferable that at least one of the source electrode and the drain electrode of the organic thin film light-emitting transistor according to the invention be an electron-injecting electrode in order to improve the electron injection capability. The electron-injecting electrode is an electrode that includes a material having a work function of 4.3 eV or less.

It is more preferable that the organic thin film light-emitting transistor according to the invention have a configuration in which one of the source electrode and the drain electrode is the hole-injecting electrode, and the other of the source electrode and the drain electrode is the electron-injecting electrode.

It is preferable to insert a hole-injecting layer between at least one of the source electrode and the drain electrode and the organic semiconductor layer in order to improve the hole injection capability. The hole-injecting layer may be formed of an amine-based material that is used as a hole-injecting material and a hole-transporting material for an organic EL device.

It is also preferable to insert an electron-injecting layer between at least one of the source electrode and the drain electrode and the organic semiconductor layer in order to improve the electron injection capability. The electron-injecting layer may be formed of an electron-injecting material that is used for an organic EL device.

It is more preferable that the organic thin film light-emitting transistor according to the invention have a configuration in which the hole-injecting layer is provided between one of the source electrode and the drain electrode and the organic semiconductor layer, and the electron-injecting layer is provided between the other of the source electrode and the drain electrode and the organic semiconductor layer.

A device that utilizes the organic thin film transistor according to the invention is not particularly limited as long as the organic thin film transistor according to the invention is used. Examples of such a device include a circuit, a personal computer, a display, a mobile phone, and the like.

### EXAMPLES

### Synthesis of Organic Semiconductor Material

### Example 1

### Synthesis of Compound (A-3)

### (1) Synthesis of Compound (a)

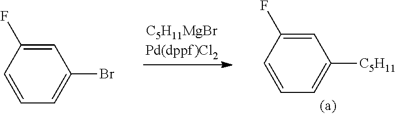

A flask was charged with 15.0 g (86 mmol) of 1-bromo-3-fluorobenzene. After replacing the atmosphere in the flask with nitrogen, 15 ml of dehydrated THF and 0.70 g (0.86 mmol) of Pd(dppf)Cl₂′CH₂Cl₂ (dichloro(diphenylphosphinoferrocene)palladium-methylene chloride complex) were added to the flask. After the addition of 130 ml (0.13 mol) of 1 M n-pentylmagnesium bromide, the mixture was stirred at room temperature for 10 minutes, and then stirred at 60° C. for 11 hours with heating. After cooling the reaction mixture, methanol, purified water, and a saturated NH₄Cl aqueous solution were added to the reaction mixture, followed by extraction with hexane. The organic layer was washed with a saturated sodium chloride solution, and dried over MgSO₄, and the solvent was removed to obtain a crude purified product of the compound (a). The crude purified product was purified by column chromatography to obtain 12.5 g of the compound (a) (yield: 88%).

### (2) Synthesis of Compound (b)

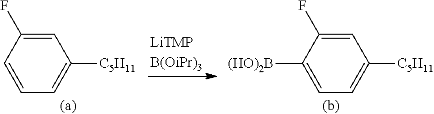

A flask in which the atmosphere had been replaced with nitrogen, was charged with 16 g (0.113 mmol) of 2,2,6,6-tetramethylpiperidine and 150 ml of dehydrated THF. After cooling the mixture to −46° C., 68 ml (0.113 mmol) of 1.67 M n-butyllithium was added to the mixture. The mixture was stirred at −20° C. for 20 minutes. After cooling the mixture to −74° C., 35 ml (0.152 mmol) of triisopropyl borate was added to the mixture. After stirring the mixture for 5 minutes, a solution prepared by dissolving 12.5 g (75 mmol) of the compound (a) in 15 ml of dehydrated THF was added dropwise to the mixture. After removing a cooling bath, the mixture was stirred at room temperature for 10 hours. After cooling the reaction mixture, a 5% HCl solution was added to the reaction mixture. The mixture was stirred at room temperature for 30 minutes, followed by extraction with ethyl acetate. The organic layer was washed with a saturated sodium chloride solution, and dried over MgSO₄, and the solvent was removed to obtain a crude purified product of the compound (b). The crude purified product was purified by column chromatography to obtain 10.4 g of the compound (b) (yield: 66%).

### (3) Synthesis of Compound (c)

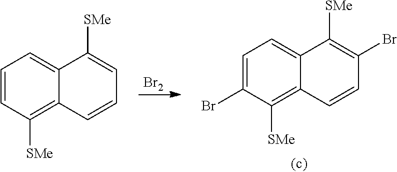

A flask was charged with 20.0 g (90.7 mmol) of 1,5-bis(methylsulfanyl)naphthalene and 400 ml of CH₂Cl₂. The mixture was stirred at 40° C. with heating. After the dropwise addition of 31.9 g (199 mmol) of bromine, the mixture was stirred at 40° C. for 8 hours with heating. After allowing the mixture to stand at room temperature for 12 hours, precipitated yellow needle-like crystals were filtered off to obtain a crude purified product of the compound (c). The crude purified product was recrystallized from ethyl acetate to obtain 22.1 g of the compound (c) (yield: 64%).

### (4) Synthesis of Compound (d)

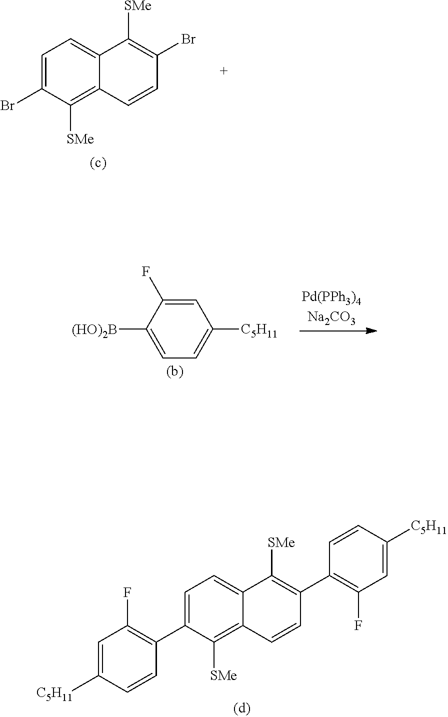

A flask in which the atmosphere had been replaced with nitrogen, was charged with 5.0 g (13 mmol) of the compound (c), 7.5 g (36 mmol) of the compound (b), 0.6 g (0.52 mmol) of tetrakis(triphenylphosphine)palladium(0), and 110 ml of dimethoxyethane, and the mixture was stirred. After the addition of a solution prepared by dissolving 11.5 g (111 mmol) of sodium carbonate in 55 ml of purified water, the mixture was refluxed for 10 hours with heating. After extraction with toluene, the organic layer was washed with a saturated sodium chloride solution, and dried over MgSO₄, and the solvent was removed to obtain a crude purified product of the compound (d). The crude purified product was purified by column chromatography to obtain 7.1 g of the compound (d) (yield: 98%).

### (4) Synthesis of Compound (A-3)

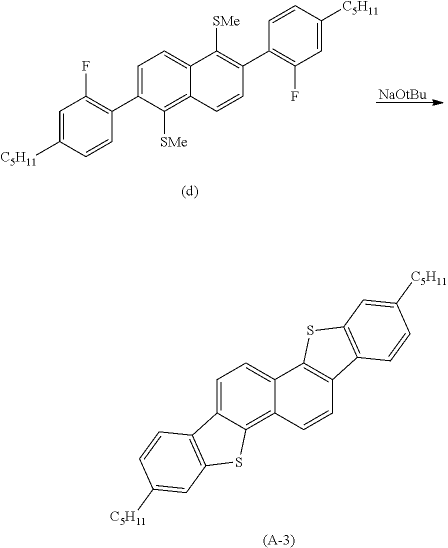

A flask was charged with 7.1 g (13 mmol) of the compound (d), 6.2 g (65 mmol) of sodium tert-butoxide, and 110 ml of dehydrated 1-methyl-2-pyrrolidone. The mixture was stirred at 160° C. for 6 hours with heating. After cooling the reaction mixture, methanol was added to the reaction mixture. The mixture was filtered to obtain a crude purified product of the compound (A-3). The crude purified product was purified by recrystallization and sublimation to obtain 3.0 g of the compound (A-3) (yield: 48%).

The structure of the compound (A-3) was determined by field desorption mass spectrometry (FD-MS). The FD-MS measurement results are shown below.

FD-MS, calcd for C₃₂H₃₂S₂=480, found, m/z=480 (M+, 100)

The FD-MS measurement conditions are shown below.

System: HX110 (manufactured by JEOL Ltd.)
Conditions: Accelerating voltage: 8 kV
Scan range: nm/z=50 to 1500

### Example 2

A compound (A-5) was synthesized in the same manner as in Example 1, except that n-heptylmagnesium bromide was used instead of n-pentylmagnesium bromide.

The structure of the compound (A-5) was determined by field desorption mass spectrometry (FD-MS). The FD-MS measurement results are shown below.

FD-MS, calcd for C₃₆H₄₀S₂=536, found, m/z=536 (M+, 100)

### Example 3

A compound (A-6) was synthesized in the same manner as in Example 1, except that n-octylmagnesium bromide was used instead of n-pentylmagnesium bromide.

The structure of the compound (A-6) was determined by field desorption mass spectrometry (FD-MS). The FD-MS measurement results are shown below.

FD-MS, calcd for C₃₈H₄₄S₂=564, found, m/z=564 (M+, 100)

### Example 4

A compound (A-9) was synthesized in the same manner as in Example 1, except that n-undecylmagnesium bromide was used instead of n-pentylmagnesium bromide.

The structure of the compound (A-9) was determined by field desorption mass spectrometry (FD-MS). The FD-MS measurement results are shown below.

FD-MS, calcd for C₄₄H₅₂S₂=644, found, m/z=644 (M+, 100)

### Example 5

A compound (B-3) was synthesized in the same manner as in Example 1, except that 1-bromo-4-fluorobenzene was used instead of 1-bromo-3-fluorobenzene.

The structure of the compound (B-3) was determined by field desorption mass spectrometry (FD-MS). The FD-MS measurement results are shown below.

FD-MS, calcd for C₃₂H₃₂S₂=480, found, nm/z=480 (M+, 100)

### Example 6

A compound (B-5) was synthesized in the same manner as in Example 5, except that n-heptylmagnesium bromide was used instead of n-pentylmagnesium bromide.

The structure of the compound (B-5) was determined by field desorption mass spectrometry (FD-MS). The FD-MS measurement results are shown below.

FD-MS, calcd for C₃₆H₄₀S₂=536, found, nm/z=536 (M+, 100)

### Example 7

A compound (B-6) was synthesized in the same manner as in Example 5, except that n-octylmagnesium bromide was used instead of n-pentylmagnesium bromide.

The structure of the compound (B-6) was determined by field desorption mass spectrometry (FD-MS). The FD-MS measurement results are shown below.

FD-MS, calcd for C₃₈H₄₄S₂=564, found, m/z=564 (M+, 100)

### Example 8

A compound (B-7) was synthesized in the same manner as in Example 5, except that n-nonylmagnesium bromide was used instead of n-pentylmagnesium bromide.

The structure of the compound (B-7) was determined by field desorption mass spectrometry (FD-MS). The FD-MS measurement results are shown below.

FD-MS, calcd for C₄₀H₄₈S₂=592, found, nm/z=592 (M+, 100)

### Example 9

A compound (B-10) was synthesized in the same manner as in Example 5, except that n-dodecylmagnesium bromide was used instead of n-pentylmagnesium bromide.

The structure of the compound (B-10) was determined by field desorption mass spectrometry (FD-MS). The FD-MS measurement results are shown below.

FD-MS, calcd for C₄₆H₆₀S₂=676, found, nm/z=676 (M+, 100)

### Example 10

A compound (C-7) was synthesized in the same manner as in Example 3, except that 1-bromo-2-fluorobenzene was used instead of 1-bromo-3-fluorobenzene.

The structure of the compound (C-7) was determined by field desorption mass spectrometry (FD-MS). The FD-MS measurement results are shown below.

FD-MS, calcd for C₃₈H₄₄S₂=564, found, m/z=564 (M+, 100)

### Example 11

A compound (D-2) was synthesized in the same manner as in Example 1, except that 1,2-dichloro-4-fluorobenzene was used instead of 1-bromo-3-fluorobenzene, and n-butylmagnesium chloride was used instead of n-pentylmagnesium bromide.

The structure of the compound (D-2) was determined by field desorption mass spectrometry (FD-MS). The FD-MS measurement results are shown below.

FD-MS, calcd for C₃₈H₄₄S₂=564, found, m/z=564 (M+, 100)

### Comparative Example 1

A comparative compound (1) was synthesized in the same manner as in Example 1, except that n-dodecylmagnesium bromide was used instead of n-pentylmagnesium bromide.

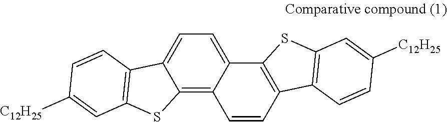

The structure of the comparative compound (1) was determined by field desorption mass spectrometry (FD-MS). The FD-MS measurement results are shown below.

FD-MS, calcd for C₄₆H₆₀S₂=676, found, m/z=676 (M+, 100)

### Evaluation of Solubility

The solubility of the compounds (A-3), (A-5), (A-6), (A-9), (B-3), (B-5), (B-6), (B-7), (B-10), (C-7), and (D-2) and the comparative compound (1) obtained in Examples 1 to 11 and Comparative Example 1 was evaluated by measuring the temperature of toluene required to dissolve each compound in toluene at a concentration of 0.4 mass %. The results are shown in Table 1.

The solubility of the comparative compound (2) shown below that was prepared by a known method was similarly evaluated. However, the comparative compound (2) was not sufficiently dissolved in the solvent.

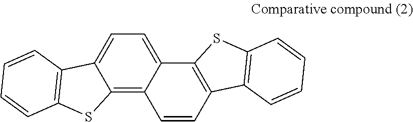 [SMILES: c1ccc2c(c1)sc1c2ccc2c1ccc1c3ccccc3sc12]

TABLE 1

| Organic | |
|---|---|
| semiconductor material | Dissolution temperature (° C.) in toluene |
| Compound A-3 | 80 |
| Compound A-5 | 80 |
| Compound A-6 | 50 |
| Compound A-9 | 70 |
| Compound B-3 | 70 |
| Compound B-5 | 70 |
| Compound B-6 | 50 |
| Compound B-7 | 60 |
| Compound B-10 | 70 |
| Compound C-7 | Room temperature |
| Compound D-2 | Room temperature |
| Comparative compound (1) | 90 |
| Comparative compound (2) | Insoluble |

The comparative compound (1) produced a solution (coating liquid) at a high temperature of 90° C. In this case, the number of parameters (e.g., evaporation of the solvent during production of the coating liquid, and temperature control during the film-forming process) that must be controlled increases, and power consumption also increases.

### Production of Organic Thin Film Transistor by Coating Method

### Example 12

An organic thin film transistor was produced as described below.

A glass substrate was subjected to ultrasonic cleaning for 30 minutes using a neutral detergent, purified water, acetone, and ethanol, respectively. Gold (Au) was deposited on the glass substrate by sputtering to a thickness of 40 nm to form a gate electrode. The substrate was then placed in the deposition section of a thermal CVD system.

A Petri dish containing 250 mg of a poly(p-xylene) derivative (Parylene) (“DiX-C” manufactured by Daisan Kasei Co., Ltd.) (raw material for forming an insulator layer) was placed in the raw material vaporization section. After reducing the pressure inside the thermal CVD system to 5 Pa using a vacuum pump, the vaporization section and the polymerization section were heated to 180° C. and 680° C., respectively, and allowed to stand for 2 hours to form an insulator layer having a thickness of 1 μm on the gate electrode.

After the addition of the compound (A-3) to toluene at a concentration of 0.4 mass %, the toluene was heated to 80° C. to dissolve the compound (A-3) to prepare a coating liquid. The coating liquid thus prepared was applied to the substrate (on which the insulator layer was formed) using a spin coater (“1H-D7” manufactured by Mikasa Co., Ltd.) to form a film. The film was dried at 80° C. in a nitrogen atmosphere to form an organic semiconductor layer having a thickness of 50 nm. Next, gold (Au) was deposited via a metal mask to a thickness of 50 nm using a vacuum deposition system to form a source electrode and a drain electrode at an interval (channel length L) of 250 μm. The source electrode and the drain electrode were formed to have a width (channel width W) of 5 mm. An organic thin film transistor was thus obtained (see FIG. 3).

A current was caused to flow between the source electrode and the drain electrode of the organic thin film transistor by applying a gate voltage V_{G} of −70 V to the gate electrode. In this case, holes were induced in the channel region (i.e., the region between the source electrode and the drain electrode) of the organic semiconductor layer, and the organic thin film transistor operated as a p-type transistor. The field-effect mobility p of holes was calculated by the following expression (A), and found to be 1.1×10⁻¹ cm²/Vs.

I_{D}=(W/2L)·C·μ·(V_{G}−V_{T})² (A)

where, I_{D} is the source-drain current, W is the channel width, L is the channel length, C is the capacitance of the gate insulator layer per unit area, p is the field-effect mobility, V_{T} is the gate threshold voltage, and V_{G} is the gate voltage. The application of the voltage and the measurement of the current between the source electrode and the drain electrode were performed using a semiconductor characterization system (“4200SCS” manufactured by Keithley Instruments Inc.).

### Example 13

A solution prepared by dissolving the compound (B-3) in toluene (70° C.) at a concentration of 0.4 mass % was applied to an insulator layer formed in the same manner as in Example 12 using a spin coater (“1H-D7” manufactured by Mikasa Co., Ltd.) to form a film. The film was dried at 80° C. in a nitrogen atmosphere to form an organic semiconductor layer having a thickness of 50 nm. Next, electrodes were formed in the same manner as in Example 12 to obtain an organic thin film transistor.

The organic thin film transistor (p-type transistor) was driven (gate voltage V_{G}: −70 V) in the same manner as in Example 12. The ON/OFF ratio of the current between the source electrode and the drain electrode was measured, and the field-effect mobility μ of holes was calculated. The results are shown in Table 2.

### Example 14

A solution prepared by dissolving the compound (B-6) in toluene (50° C.) at a concentration of 0.4 mass % was applied to an insulator layer formed in the same manner as in Example 12 using a spin coater (“1H-D7” manufactured by Mikasa Co., Ltd.) to form a film. The film was dried at 80° C. in a nitrogen atmosphere to form an organic semiconductor layer having a thickness of 50 nm. Next, electrodes were formed in the same manner as in Example 12 to obtain an organic thin film transistor.

The organic thin film transistor (p-type transistor) was driven (gate voltage V_{G}: −70 V) in the same manner as in Example 12. The ON/OFF ratio of the current between the source electrode and the drain electrode was measured, and the field-effect mobility p of holes was calculated. The results are shown in Table 2.

### Example 15

A solution prepared by dissolving the compound (B-10) in toluene (70° C.) at a concentration of 0.4 mass % was applied to an insulator layer formed in the same manner as in Example 12 using a spin coater (“1H-D7” manufactured by Mikasa Co., Ltd.) to form a film. The film was dried at 80° C. in a nitrogen atmosphere to form an organic semiconductor layer having a thickness of 50 nm. Next, electrodes were formed in the same manner as in Example 12 to obtain an organic thin film transistor.

The organic thin film transistor (p-type transistor) was driven (gate voltage V_{G}: −70 V) in the same manner as in Example 12. The ON/OFF ratio of the current between the source electrode and the drain electrode was measured, and the field-effect mobility p of holes was calculated. The results are shown in Table 2.

### Example 16

A solution prepared by dissolving the compound (D-2) in toluene (room temperature) at a concentration of 0.4 mass % was applied to an insulator layer formed in the same manner as in Example 12 using a spin coater (“1H-D7” manufactured by Mikasa Co., Ltd.) to form a film. The film was dried at 80° C. in a nitrogen atmosphere to form an organic semiconductor layer having a thickness of 50 nm. Next, electrodes were formed in the same manner as in Example 12 to obtain an organic thin film transistor.

The organic thin film transistor (p-type transistor) was driven (gate voltage V_{G}: −70 V) in the same manner as in Example 12. The ON/OFF ratio of the current between the source electrode and the drain electrode was measured, and the field-effect mobility p of holes was calculated. The results are shown in Table 2.

### Comparative Example 2

An organic thin film transistor was obtained in the same manner as in Example 12 except that the comparative compound (1) was used as the material for forming the organic semiconductor layer instead of the compound (A-3), and heated at 90° C. to prepare a coating liquid. The organic thin film transistor (p-type transistor) was driven (gate voltage V_{G}: −70 V) in the same manner as in Example 12. However, the field-effect mobility was very low.

It is considered that the organic semiconductor layer was not uniformly formed since the film was formed at 90° C. (that is close to the boiling point of toluene) in order to maintain the solubility of the organic semiconductor material, and the field-effect mobility significantly decreased due to discontinuity of the crystal grains and the like.

TABLE 2

| | Organic | Field-effect mobility |
|---|---|---|
| | semiconductor layer | (cm²/Vs) |
| Example 12 | Compound (A-3) | 1.1 × 10⁻¹ |
| Example 13 | Compound (B-3) | 1.3 × 10⁻¹ |
| Example 14 | Compound (B-6) | 5.3 × 10⁻² |
| Example 15 | Compound (B-10) | 5.2 × 10⁻² |
| Example 16 | Compound (D-2) | 3.5 × 10⁻² |
| Comparative Example 2 | Comparative | 1.1 × 10⁻⁴ |
| | compound 1 | |

### Production of Organic Thin Film Transistor by Deposition Method

### Example 17

An organic thin film transistor was produced as described below. The surface of an Si substrate (P-type, specific resistance: 1 ∩·cm, the Si substrate also serves as a gate electrode) was oxidized by a thermal oxidation method to form a thermal oxide film (insulator layer) having a thickness of 300 nm on the substrate. After completely removing the SiO₂ film formed on one side of the substrate by dry etching, chromium was deposited by sputtering to a thickness of 20 nm, and gold (Au) was deposited on the chromium film by sputtering to a thickness of 100 nm to form a lead-out electrode. The substrate was subjected to ultrasonic cleaning for 30 minutes using a neutral detergent, purified water, acetone, and ethanol, respectively, and then subjected to ozone cleaning.

The substrate was placed in a vacuum deposition system (“EX-400” manufactured by ULVAC, Inc.), and the compound (A-3) was deposited on the insulator layer at a deposition rate of 0.05 nm/s to form an organic semiconductor layer having a thickness of 50 nm. Next, gold (Au) was deposited via a metal mask to a thickness of 50 nm to form a source electrode and a drain electrode at an interval (channel length L) of 50 μm. The source electrode and the drain electrode were formed to have a width (channel width W) of 1 mm. An organic thin film transistor was thus obtained.

A current was caused to flow between the source electrode and the drain electrode of the organic thin film transistor by applying a gate voltage of 0 to −100 V to the gate electrode, and by applying a voltage of 0 to −100 V to between the source electrode and the drain electrode. In this case, electrons were induced in the channel region (i.e., the region between the source electrode and the drain electrode) of the organic semiconductor layer, and the organic thin film transistor operated as a p-type transistor. The field-effect mobility p of holes in the current saturation region was 1.1 cm²Ns.

### Example 18

The compound (A-6) was deposited on an insulator layer that was formed in the same manner as in Example 17. Next, electrodes were formed in the same manner as in Example 17 to obtain an organic thin film transistor.

The field-effect mobility p of holes in the organic thin film transistor was calculated in the same manner as in Example 17. The results are shown in Table 3.

### Example 19

The compound (A-9) was deposited on an insulator layer that was formed in the same manner as in Example 17. Next, electrodes were formed in the same manner as in Example 17 to obtain an organic thin film transistor.

The field-effect mobility μ of holes in the organic thin film transistor was calculated in the same manner as in Example 17. The results are shown in Table 3.

### Example 20

The compound (B-3) was deposited on an insulator layer that was formed in the same manner as in Example 17. Next, electrodes were formed in the same manner as in Example 17 to obtain an organic thin film transistor.

The field-effect mobility p of holes in the organic thin film transistor was calculated in the same manner as in Example 17. The results are shown in Table 3.

### Example 21

The compound (B-5) was deposited on an insulator layer that was formed in the same manner as in Example 17. Next, electrodes were formed in the same manner as in Example 17 to obtain an organic thin film transistor.

The field-effect mobility p of holes in the organic thin film transistor was calculated in the same manner as in Example 17. The results are shown in Table 3.

### Example 22

The compound (B-6) was deposited on an insulator layer that was formed in the same manner as in Example 17. Next, electrodes were formed in the same manner as in Example 17 to obtain an organic thin film transistor.

The field-effect mobility p of holes in the organic thin film transistor was calculated in the same manner as in Example 17. The results are shown in Table 3.

### Example 23

The compound (B-10) was deposited on an insulator layer that was formed in the same manner as in Example 17. Next, electrodes were formed in the same manner as in Example 17 to obtain an organic thin film transistor.

The field-effect mobility μ of holes in the organic thin film transistor was calculated in the same manner as in Example 17. The results are shown in Table 3.

### Comparative Example 3

An organic thin film transistor was obtained in the same manner as in Example 17, except that the comparative compound (1) was used as the material for forming the organic semiconductor layer instead of the compound (A-3).

The field-effect mobility μ of holes in the organic thin film transistor was calculated in the same manner as in Example 17. The results are shown in Table 3.

TABLE 3

| | | Field-effect mobility |
|---|---|---|
| | Organic semiconductor layer | (cm²/Vs) |
| Example 17 | Compound (A-3) | 1.1 × 10⁻⁰ |
| Example 18 | Compound (A-6) | 2.3 × 10⁻¹ |
| Example 19 | Compound (A-9) | 2.0 × 10⁻¹ |
| Example 20 | Compound (B-3) | 6.0 × 10⁻¹ |
| Example 21 | Compound (B-5) | 6.1 × 10⁻¹ |
| Example 22 | Compound (B-6) | 3.5 × 10⁻¹ |
| Example 23 | Compound (B-10) | 6.5 × 10⁻¹ |
| Comparative | Comparative compound (1) | 1.2 × 10⁻¹ |
| Example 3 | | |

As shown in Table 3, it was confirmed that the material according to the invention is an excellent organic semiconductor material.

### Determination of Storage Stability of Organic Semiconductor Material

### Example 24

The organic thin film transistor obtained in Example 17 was stored for 9 days in air, and the carrier mobility was calculated, and found to be 1.1 cm²/Vs (i.e., a deterioration in carrier mobility was not observed).

### Comparative Example 4

An organic thin film transistor was obtained in the same manner as in Example 17, except that pentacene (see the following formula) was used as the material for forming the organic semiconductor layer instead of the compound (A-3).

The field-effect mobility μ of holes in the organic thin film transistor was calculated in the same manner as in Example 17, and found to be 3.8×10¹ cm²/Vs. The carrier mobility calculated after storing the organic thin film transistor for 9 days in air was 1.3×10³ cm²/Vs.

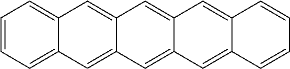 [SMILES: c1ccc2cc3cc4cc5ccccc5cc4cc3cc2c1]

### INDUSTRIAL APPLICABILITY

As described in detail above, the organic semiconductor material according to the invention may be used as a material for forming an organic semiconductor layer of an organic thin film transistor that is formed by the coating method. Since the organic semiconductor material according to the invention exhibits high carrier mobility as a material for forming an organic semiconductor layer, an organic thin film transistor produced using the organic semiconductor material according to the invention has a high response speed (driving speed), and exhibits high transistor performance.

Although only some exemplary embodiments and/or examples of the invention have been described in detail above, those skilled in the art will readily appreciate that many modifications are possible in the exemplary embodiments and/or examples without materially departing from the novel teachings and advantages of the invention. Accordingly, all such modifications are intended to be included within the scope of the invention.

The documents described in the specification are incorporated herein by reference in their entirety.

1. An organic semiconductor material represented by a formula (1), 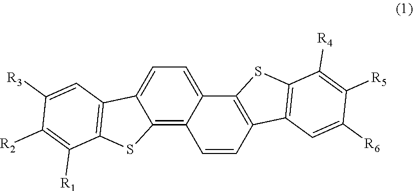
wherein R₁, R₃, R₄, and R₆ are independently a hydrogen atom, a linear alkyl group having 3 to 20 carbon atoms, or a branched alkyl group having 3 to 40 carbon atoms, and
R₂ and R₅ are independently a hydrogen atom, a linear alkyl group having 3 to 11 carbon atoms, or a branched alkyl group having 3 to 40 carbon atoms,
provided that two or more of R₁ to R₆ are an alkyl group.

2. The organic semiconductor material according to claim 1, wherein R₁, R₃, R₄, and R₆ are a hydrogen atom.

3. The organic semiconductor material according to claim 1, wherein R₁, R₂, R₄, and R₅ are a hydrogen atom.

4. The organic semiconductor material according to claim 1, wherein R₂, R₃, R₅, and R₆ are a hydrogen atom.

5. The organic semiconductor material according to claim 1, the organic semiconductor material being represented by

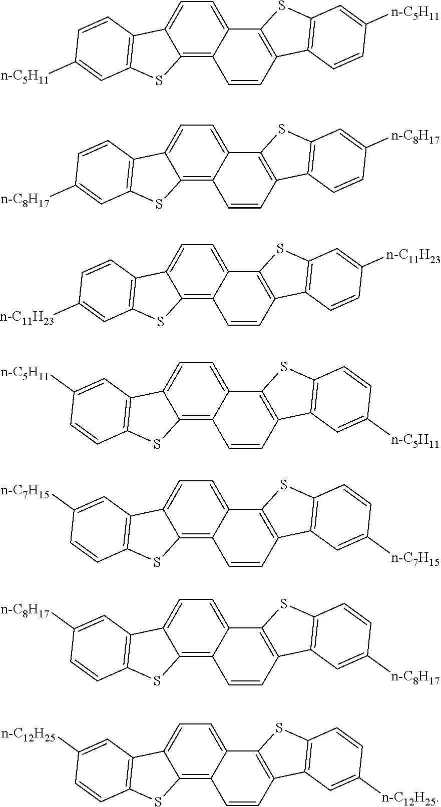

6. An organic semiconductor material represented by a formula (5), 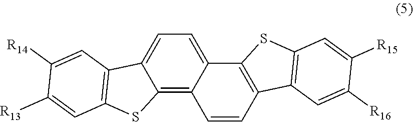
wherein R₁₃, R₁₄, R₁₅, and R₁₆ are independently a linear alkyl group having 3 to 11 carbon atoms or a branched alkyl group having 3 to 40 carbon atoms.

7. A coating liquid comprising the organic semiconductor material according to claim 1, and an organic solvent.

8. An organic thin film transistor produced using the coating liquid according to claim 7.

9. An organic thin film transistor comprising an organic semiconductor layer produced using the coating liquid according to claim 7.

10. The organic thin film transistor according to claim 8, comprising a source electrode and a drain electrode, and emitting light by utilizing a current that flows between the source electrode and the drain electrode, wherein emission of light is controlled by applying a voltage to a gate electrode.

11. The organic thin film transistor according to claim 10, wherein one of the source electrode and the drain electrode comprises a material that has a work function of 4.2 eV or more, and the other of the source electrode and the drain electrode comprises a material that has a work function of 4.3 eV or less.

12. The organic thin film transistor according to claim 10, comprising a buffer layer between the source electrode and drain electrode, and the organic semiconductor layer.

13. A device comprising the organic thin film transistor according to claim 8.
